(19) United States
(12) Patent Application Publication
(10) Pub. No.: US 2007/0278493 A1
(43) Pub. Date: Dec. 6, 2007

(54) Light-emitting element and display device

(75) Inventor: Yosuke Sato, Isehara (JP)

Correspondence Address: COOK, ALEX, MCFARRON, MANZO, CUMMINGS & MEHLER LTD, SUITE 2850, 200 WEST ADAMS STREET, CHICAGO, IL, 60606, US

(73) Assignee: Semiconductor Energy Laboratory Co., Ltd.

(21) Appl. No.: 11/804,244

(22) Filed: May 17, 2007

(30) Foreign Application Priority Data
Jun. 2, 2006 (JP) 2006-154154

(51) Int. Cl. H01L 29/04

(52) U.S. Cl. 257/72; 257/83; 257/E33.064

(57) ABSTRACT

An object is to provide a light-emitting element having high light extraction efficiency. Further, an object is to provide a light-emitting element and a display device having high luminance and low power consumption. A light-emitting element of the present invention includes a light-emitting layer interposed between a first and second electrodes. The light-emitting element further includes at least a dielectric layer which is interposed between the first and light-emitting layer, and light-scattering fine particles are dispersed in the dielectric layer. Light emitted from the light-emitting layer is extracted to the outside through the first electrode.

### BACKGROUND OF THE INVENTION

1. Field of the Invention

The present invention relates to light-emitting elements that emit light when electrical energy is applied, and to display devices including such a light-emitting element.

2. Description of the Related Art

In recent years, the improvement of flat panel displays typified by liquid crystal displays has proceeded. Efforts have been made to improve image quality, to decrease power consumption, to increase operating lifetime, and so on. However, the liquid crystal used in liquid crystal displays is not self-emissive. A liquid crystal layer is formed between a pair of substrates, and a light source (e.g., a backlight) is placed on one side of the pair of substrates. The images are obtained by controlling whether light from the light source is transmitted or blocked by the liquid crystals. Thus, liquid crystal displays require high electrical energy not only for controlling the liquid crystals but also for operating the light source attached to the liquid crystal displays.

Therefore, electroluminescence elements (hereinafter referred to as EL elements) are drawing attention as one of the self-emissive light-emitting elements. In addition to the self-emissive property, EL elements have advantages such as being thin and lightweight, and thus, tremendous research on them is currently progressing. To achieve full-color image in the aforementioned liquid crystal displays, it is necessary to attach a color conversion layer, called a color filter, onto the surface of the liquid crystal layer. Meanwhile, EL elements can emit light of various colors such as red, green, and blue, depending on their individual materials. Therefore, EL elements have the advantage of readily achieving full-color imaging without using a color filter, whereas light from the light source is attenuated by the color filter in a liquid crystal display.

Light-emitting elements are classified according to whether their light-emitting material is an organic compound or an inorganic compound. Generally, the former are referred to as an organic light-emitting elements, while the latter are referred to as an inorganic light-emitting element. Further, depending on their structure, inorganic light-emitting elements are classified as thin-film inorganic light-emitting elements or dispersion-type inorganic light-emitting elements. These light-emitting elements are different in structure. The former include a light-emitting layer formed of a thin film of light-emitting material, while the latter include a light-emitting layer in which particles of light-emitting material are dispersed in a binder. The emission mechanism for both types of light-emitting elements involves the donor-acceptor recombination light emission utilizing a donor level and an acceptor level or localized light emission utilizing an inner-shell electron transition of a metal ion. Generally, localized light emission mechanism is employed in thin-film inorganic light-emitting elements, while the donor-acceptor recombination light emission mechanism is employed in dispersion-type inorganic light-emitting elements.

In order to utilize the self-emissive property of the light-emitting elements in the practical application of electroluminescence panels (hereinafter also referred to as EL panels) which employ light-emitting elements in pixels, it is desired to realize bright and vivid displays with low power consumption. For this purpose, improvement in power efficiency has been achieved by improving the current-luminance characteristics of materials used for the light-emitting elements. However, there is a limit to improving power efficiency by the method described above.

The light emitted from a light-emitting layer of a light-emitting element is not quantitatively extracted to the outside. When the light passes an interface between films that have different refractive indices, some of the light is totally reflected. The totally reflected light is then absorbed by the light-emitting element and attenuates. Therefore, the efficiency of extraction of light to the outside decreases.

Reference 1 describes an EL element that has improved light extraction efficiency, which was achieved by reducing the amount of total reflection (Reference 1: Japanese Published Patent Application No. 2004-303724). In Reference 1, a film in which particles are dispersed is provided over a transparent electrode layer so that light which passes through the inside of the film is scattered by the particles, and thus, light incident on the interface between the transparent electrode layer and a low refractive index film has an incident angle which is less than the critical angle.

### SUMMARY OF THE INVENTION

An object of the present invention is to reduce the amount of light emitted from the light-emitting layer that is totally reflected, and thereby increase the amount of light extracted to the outside by a means different from that described in Reference 1, thereby enabling fabrication of a light-emitting element with high light extraction efficiency. Further, an object of the invention is to provide a light-emitting element and a display device that have high luminance and low power consumption.

A light-emitting element of the invention includes a light-emitting layer interposed between a first electrode and a second electrode which face each other. The light-emitting element further includes at least a dielectric layer which is interposed between the first electrode and the light-emitting layer, and light-scattering fine particles are dispersed in the dielectric layer. Light emitted from the light-emitting layer is extracted to the outside through the first electrode.

Further, in the light-emitting element with the structure described above, a dielectric layer may also be provided between the second electrode and the light-emitting layer. Further, two dielectric layers in which light-scattering fine particles are dispersed may be provided between the first electrode and the light-emitting layer.

Another structure of the light-emitting element of the invention includes a light-emitting layer interposed between the first electrode and the second electrode which face each other, and the light-emitting layer has a structure in which particles of light-emitting material and light-scattering fine particles are dispersed in a binder. Light emitted from the light-emitting layer is extracted to the outside through the first electrode.

Further, in the above structure of the light-emitting element, a dielectric layer in which light-scattering fine particles are dispersed may be additionally provided between the first electrode and the light-emitting layer.

The light-scattering fine particles are fine particles which are formed using an organic material or an inorganic material. Further, it is preferable that the refractive index of the light-scattering fine particles is equal to or greater than the refractive index of the first electrode through which light is extracted. Note that when an electrode is a single layer film, the refractive index of the electrode refers to the refractive index of the single layer film. When an electrode is a film having a plurality of layers, the refractive index of the electrode refers to the refractive index of the layer of the electrode that is outermost in the light-emitting element.

The light-scattering fine particles preferably have a size (a particle diameter) that allows light emitted from the light-emitting layer to be refracted and scattered so that the light can pass through an interface between the dielectric layer and the first electrode. Specifically, the average size of the light-scattering fine particles is preferably equal to or greater than 2 nm, and more preferably, it is equal to or greater than 20 nm. Further, the average size of the fine particles preferably does not exceed a wavelength in the visible light region. Specifically, the average size of the light-scattering fine particles is preferably equal to or less than 800 nm, and taking an optical design of the light-emitting element into consideration, the size is preferably equal to or less than 100 nm.

Further, the first electrode preferably has a light-transmitting property, so that light emitted from the light-emitting layer is extracted through the first electrode.

In the invention, by providing a plurality of fine particles having a predetermined refractive index in a dielectric layer or a light-emitting layer, the incident angle of light that passes from the light-emitting layer through the dielectric layer or the incident angle of light that passes from the light-emitting material dispersed in the light-emitting layer through the light-emitting layer is diversified. Thus, light that would be totally reflected at an interface with an electrode in the case of the conventional structure can also be extracted to the outside. Therefore, the light extraction efficiency of a light-emitting element can be improved.

The refractive index of the light-scattering fine particles is preferably equal to or greater than that of the electrode, so that light which passes through the light-scattering fine particles is not totally reflected at an interface with the electrode.

A display device of the invention includes a light-emitting element having one of the above structures interposed between a first substrate and a second substrate which face each other. Light from the light-emitting element is extracted through the first substrate. Further, a sealant for sealing the light-emitting element is provided between the first substrate and the second substrate.

The sealant is provided at the periphery of the first substrate and the second substrate. It is preferable that the region, which is enclosed by the first substrate, the second substrate and the sealant, is filled with a gas, or that a solid is provided in the region. In the case of filling the region with a gas, an inert gas such as nitrogen or argon is preferably used. Further, in the case of providing a solid in the region, a resin is preferably used.

A substrate with a high transmittance with respect to visible light is preferably used as the first substrate, so that light emitted from the light-emitting element is extracted through the first substrate. Specifically, the first substrate preferably has a transmittance of equal to or greater than 80% with respect to visible light.

According to the invention, when light emitted from a light-emitting layer is extracted through an electrode, the amount of light that is totally reflected is reduced. Therefore, the light extraction efficiency of a light-emitting element can be improved. Further, by utilizing the light-emitting element having high light extraction efficiency in a display device, a display device with high luminance and low power consumption can be obtained.

### BRIEF DESCRIPTION OF DRAWINGS

FIGS. 1A and 1B are cross sections of a display device (Embodiment Mode 1).

FIGS. 2A and 2B are cross sections of a display device (Embodiment Mode 2).

FIGS. 3A to 3D are cross sections of a display device (Embodiment Mode 3).

FIGS. 4A to 4D are cross sections of a display device (Embodiment Mode 4).

FIG. 5 is a cross section of a display device (Embodiment Mode 5).

FIG. 6 is a cross section of a display device (Embodiment Mode 6).

FIG. 7 is a cross section of a display device (Embodiment Mode 7).

FIG. 8 is a cross section of a display device (Embodiment Mode 8).

FIGS. 9A to 9C are cross sections of a display device (Embodiment Mode 9).

FIGS. 10A to 10C are cross sections of a display device (Embodiment Mode 10).

FIG. 11 is an elevation view of a display device (Embodiment Mode 11).

FIG. 12 illustrates a circuit of a pixel in a display device (Embodiment Mode 11).

FIG. 13 is a cross section of a pixel in a display device (Embodiment Mode 11).

FIG. 14 illustrates a driving method of a display device (Embodiment Mode 11).

FIGS. 15A to 15F illustrate modes of applying a display device to electronic devices (Embodiment Mode 12).

FIG. 16 illustrates a mode of applying a display device to a planar lighting device (Embodiment Mode 13).

FIGS. 17A and 17B are a perspective view and a cross section, respectively, of a display device (Embodiment Mode 11).

### DETAILED DESCRIPTION OF THE INVENTION

### Embodiment Modes

Hereinafter, embodiment modes of the invention will be described with reference to the accompanying drawings. However, the invention can be implemented in many different modes. Those skilled in the art will readily appreciate that a variety of modifications can be made to the modes and their details without departing from the spirit and scope of the invention. The invention should not be construed as being limited to the description in the embodiment modes below.

Further, the embodiment modes can be combined as appropriate without departing from the spirit of the invention. In the embodiment modes, description is made using like reference numerals for the like parts. Therefore, some description is omitted.

### Embodiment Mode 1

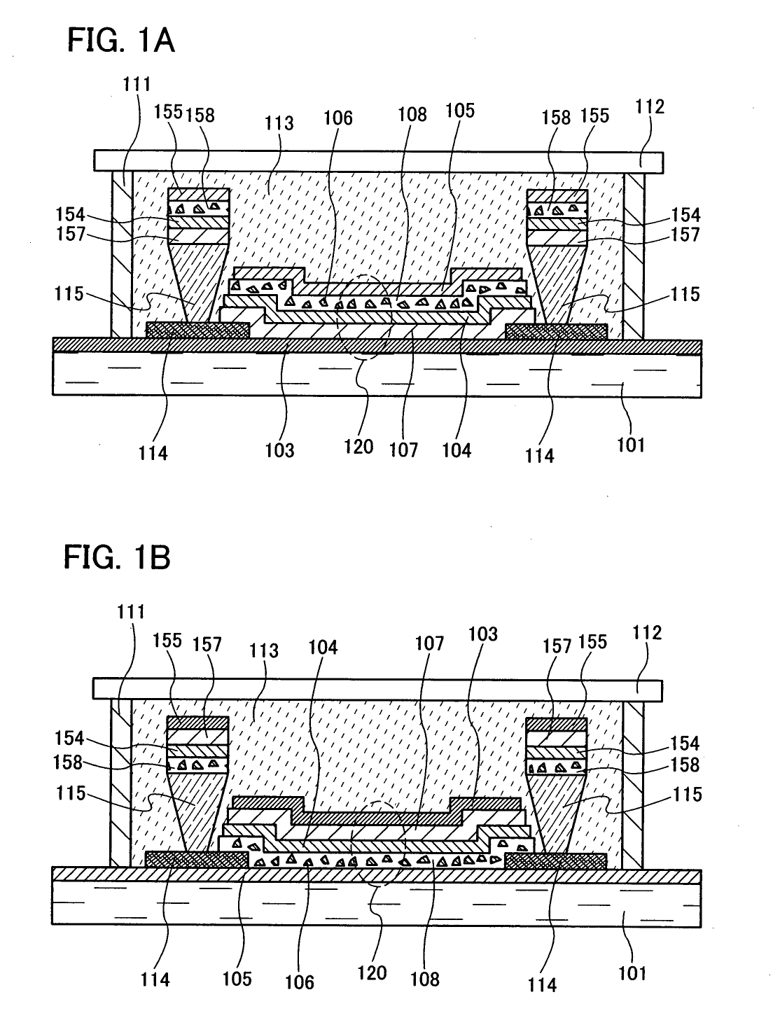

In this embodiment mode, a mode employing a thin film inorganic light-emitting element which is a light-emitting element of the invention will be described. FIG. 1A shows a cross section of a display device employing a top emission structure. Further, FIG. 1B shows a cross section of a display device employing a bottom emission structure. Note that in this specification, a top emission structure refers to a structure in which light emitted from a light-emitting element is extracted through the upper side (the sealing substrate side). On the other hand, a bottom emission structure refers to a structure in which light emitted from the light-emitting element is extracted through the lower side (the side on which there is a substrate over which an element is provided).

In this embodiment mode, FIGS. 1A and 1B differ in structure only in that the positions and order of formation of a reflective electrode 103 and a transmissive electrode 105 and of a first dielectric layer 107 and a second dielectric layer 108 are reversed. Therefore, unless specific explanation is not given, description will be made with reference to the top emission structure in FIG. 1A.

FIG. 1A shows a cross section of a display device including a light-emitting element of the invention. A light-emitting element 120 is provided over a substrate 101.

In the light-emitting element 120, the reflective electrode 103, the first dielectric layer 107, a light-emitting layer 104, the second dielectric layer 108, and the transmissive electrode 105 are layered in that order from the substrate 101 side. A plurality of light-scattering fine particles 106 are dispersed in the second dielectric layer 108.

It is preferable that the light-emitting layer 104 of the light-emitting element 120 is separated by an insulating layer 114, which covers a part of the reflective electrode 103, and a partition layer 115. In this embodiment mode, the first dielectric layer 107, the light-emitting layer 104, the second dielectric layer 108, and the transmissive electrode 105 are separated by the insulating layer 114 and the partition layer 115. Further, a separated first dielectric layer 157, a separated light-emitting layer 154, a separated second dielectric layer 158, and a separated transmissive electrode 155 are layered over the partition layer 115. The partition layer 115 has an inclination such that the shorter the distance to a surface of the substrate, the shorter the distance between one sidewall and the other sidewall. That is, a cross section taken along the direction of the shorter side of the partition layer 115 has a trapezoidal shape, and the base of the trapezoid (the side of the trapezoid that is parallel to a surface of the insulating layer 114 and is in contact with the insulating layer 114) is shorter than the upper side of the trapezoid (the side of the trapezoid that is parallel to the surface of the insulating layer 114 and is not in contact with the insulating layer 114). By providing the partition layer 115 in this manner, it is possible to electrically separate the transmissive electrode 105 from the adjacent transmissive electrode. Note that the insulating layer 114 and the partition layer 115 are not necessarily provided.

Further, by using a sealant 111 provided at the periphery of the substrate 101, a sealing substrate 112 is fixed to the substrate 101, and the light-emitting element 120 is sealed. In this embodiment mode, an airtight space made by the substrate 101, the sealant 111, and the substrate 112 is filled with a gas 113. Preferably, an inert gas such as nitrogen or argon is used as the gas 113 which fills the space.

As the substrate 101, any substrate which acts as a support substrate for the light-emitting element 120 may be used. For example, a quartz substrate, a semiconductor substrate, a glass substrate, a plastic substrate, a plastic film that has flexibility, or the like can be used.

As the sealing substrate 112, a quartz substrate, a semiconductor substrate, a glass substrate, a plastic substrate, a plastic film that has flexibility, or the like can be used. In this embodiment mode, a tabular substrate is used as the sealing substrate 112. However, the shape of the sealing substrate is not limited to this shape, and a substrate with a different shape can be used, as long as it is capable of sealing the light-emitting element. For example, it is possible to use a cap-shaped substrate such as a sealing can.

When the sealing substrate 112 is the substrate through which light is extracted, a substrate with a high transmittance with respect to visible light is preferably used as the sealing substrate 112. Specifically, a substrate that has a transmittance of 80% or more with respect to visible light is preferably used. In the case where the top emission structure shown in FIG. 1A is employed, the electrode closest to the substrate 112 is an electrode with a light transmitting property (the transmissive electrode 105). The electrode closest to the substrate 101 has a reflective property (the reflective electrode 103), and the substrate 101 is on the side through which light is not extracted. Therefore, it is not necessary for the substrate 101 to be transparent. The substrate 101 may be colored, or opaque.

Further, when the substrate 101 is the substrate on the side through which light is extracted, it is preferable to use a substrate with a high transmittance with respect to visible light. Specifically, a substrate that has a transmittance of 80% or more with respect to visible light is preferably used. In the case where the bottom emission structure shown in FIG. 1B is employed, the electrode closest to the substrate 101 is an electrode with a light transmitting property (the transmissive electrode 105). The electrode closest to the sealing substrate 112 is an electrode with a reflective property (the reflective electrode 103), and the sealing substrate 112 is on the side through which light is not extracted. Therefore, it is not necessary for the sealing substrate 112 to be transparent. The sealing substrate 112 may be colored, or opaque.

Note that when the substrate 101 or the sealing substrate 112 is on the side through which light is extracted, a color filter for improving the color purity of the light-emitting element or for changing a color emitted from the light-emitting element may be provided.

Note that passive matrix type pixels are illustrated in the display devices shown in FIGS. 1A and 1B. However, when the display devices in FIGS. 1A and 1B are employed in active matrix pixels, a circuit which includes a transistor, a capacitor, and the like can be provided below the light-emitting element 120 to control the luminance and timing of the light emission of the light-emitting element 120.

The reflective electrode 103 is formed over the substrate 101. The reflective electrode 103 has a function of reflecting light emitted from the light-emitting layer, and serves as a cathode. The reflective electrode 103 is formed from a conductive film with a reflective property such as a metal film or an alloy film. As a metal film, a film formed of gold (Au), platinum (Pt), nickel (Ni), tungsten (W), chromium (Cr), molybdenum (Mo), iron (Fe), cobalt (Co), copper (Cu), palladium (Pd), aluminum (Al), or the like can be used, for example. Further, as an alloy film, a film formed of an alloy of magnesium and silver, an alloy of aluminum and lithium, or the like can be used, for example. These films that form the reflective electrode 103 can be fabricated using a sputtering method or a vapor deposition method.

Further, the reflective electrode 103 can be formed by a film having a plurality of layers, which includes a transparent conductive film layered over the aforementioned metal film or alloy film, or includes the abovementioned metal film or alloy film interposed between two transparent conductive films. Furthermore, a film having a plurality of layers formed of transparent conductive films with different refractive indices can be used as the reflective electrode 103. By utilizing optical multiple interference, high reflectivity can be realized.

Over the reflective electrode 103, the first dielectric layer 107 is formed. The first dielectric layer 107 is formed from an insulating material. There is no particular limitation on the insulating material. However, the insulating material preferably has a high withstand voltage and forms a dense film. In addition, the insulating material preferably has a high dielectric constant. For example, yttrium oxide, titanium oxide, aluminum oxide, hafnium oxide, tantalum oxide, barium titanate, strontium titanate, lead titanate, silicon nitride, zirconium oxide, or the like, or a mixed film or a layered film containing two or more of the aforementioned insulating materials can be used. The first dielectric layer 107 can be formed by a sputtering method, a vapor deposition method, a CVD method, a droplet discharge method (representatively, an inkjet method), or the like, using these materials.

The light-emitting layer 104 is formed over the first dielectric layer 107. The light-emitting layer 104 is a layer formed from a thin film of light-emitting material. A light-emitting material that can be used in this embodiment mode includes a host material and an impurity element. By varying the impurity element that is included, various colors of light emission can be obtained. A variety of methods can be used to prepare the light-emitting material. For example, a solid phase method or a liquid phase method (e.g., a coprecipitation method) can be used. Further, a liquid phase method such as a spray pyrolysis method, a double decomposition method, a method which employs a pyrolytic reaction of a precursor, a reverse micelle method, a method in which one or more of the above methods is combined with high-temperature baking, a freeze-drying method, or the like can be used.

In the solid phase method, the host material and an impurity element or a compound containing an impurity element are weighed, mixed in a mortar, and reacted by heating and baking in an electric furnace. Thereby, the impurity element is included in the host material. Baking temperature is preferably 700 to 1500° C. This is because if the temperature is too low, the solid phase reaction does not proceed, and if the temperature is too high, the host material decomposes. The materials may be baked in powdered form. However, it is preferable to bake the materials in pellet form. The solid phase method requires baking at a relatively high temperature. However, due to its simplicity, this method has high productivity and is suitable for mass production.

The liquid phase method (e.g., a coprecipitation method) is a method in which the host material or a compound containing the host material, and an impurity element or a compound containing an impurity element, are reacted in a solution, dried, and then baked. Particles of the light-emitting material can be distributed uniformly and have a small diameter. The reaction can be carried out even at a low baking temperature.

As a host material for the light-emitting material, a sulfide, an oxide, or a nitride can be used. As a sulfide, zinc sulfide, cadmium sulfide, calcium sulfide, yttrium sulfide, gallium sulfide, strontium sulfide, barium sulfide, or the like can be used, for example. Further, as an oxide, zinc oxide, yttrium oxide, or the like can be used, for example. Moreover, as a nitride, aluminum nitride, gallium nitride, indium nitride, or the like can be used, for example. Further, zinc selenide, zinc telluride, or the like can also be used. Temary mixed crystal such as calcium gallium sulfide, strontium gallium sulfide, or barium gallium sulfide may also be used.

In a case where the light-emitting element 120 described in this embodiment mode is a localized light emission type light-emitting element, manganese (Mn), copper (Cu), samarium (Sm), terbium (Th), erbium (Er), thulium (Tm), europium (Eu), cerium (Ce), praseodymium (Pr), or the like can be used as an impurity element. Further, as charge compensation, a halogen element such as fluorine (F) or chlorine (Cl) may be added.

Meanwhile, in a case where the light-emitting element 120 described in this embodiment mode is a donor-acceptor recombination type light-emitting element, it is possible to use a light-emitting material that includes a first impurity element which forms a donor level and a second impurity element which forms an acceptor level. As the first impurity element, fluorine (F), chlorine (Cl), aluminum (Al), or the like can be used, for example. As the second impurity element, copper (Cu), silver (Ag), or the like can be used, for example.

In the case of using a solid phase method to synthesize a light-emitting material for donor-acceptor recombination type light emission, the host material, the first impurity element or a compound containing the first impurity element, and the second impurity element or a compound containing the second impurity element are weighed, mixed in a mortar, then baked by heating in an electric furnace. As the host material, any of the abovementioned host materials can be used. As the first impurity element, fluorine (F), chlorine (Cl), or the like can be used, for example. As the compound containing the first impurity element, aluminum sulfide or the like can be used, for example. As the second impurity element, copper (Cu), silver (Ag), or the like can be used, for example. As the compound containing the second impurity element, copper sulfide, silver sulfide, or the like can be used, for example. Baking temperature is preferably 700 to 1500° C. This is because if the temperature is too low, the solid phase reaction does not proceed, and if the temperature is too high, the host material decomposes. Baking may be conducted with the materials in powdered form. However, it is preferable to conduct baking with the materials in pellet form.

Further, in the case of employing a solid phase reaction, a compound including the first impurity element and the second impurity element may also be used. In such a case, since the impurity elements diffuse readily and the solid phase reaction proceeds readily, a uniform light-emitting material can be obtained. Further, since an unnecessary impurity element does not contaminate the light-emitting material, a light-emitting material with high purity can be obtained. As the compound including the first impurity element and the second impurity element, for example, copper chloride, silver chloride, or the like can be used.

Note that the concentration of the impurity elements in the host material may be 0.01 to 10 atomic percent, and is preferably in the range of 0.05 to 5 atomic percent.

The light-emitting element 120 of this embodiment mode is a thin film inorganic light-emitting element, and the light-emitting layer 104 includes an abovementioned light-emitting material. As a method of formation of the light-emitting layer, a vacuum deposition method using resistive heating system, electron-beam evaporation (EB evaporation), a physical vapor deposition (PVD) method such as sputtering, a chemical vapor deposition (CVD) method such as a metal-organic CVD method or a low pressure hydride transport CVD method, an atomic layer epitaxy (ALE) method, or the like can be used.

The second dielectric layer 108 is formed over the light-emitting layer 104. Light scattering fine particles 106 are dispersed in the second dielectric layer 108. The second dielectric layer 108 is formed from an insulating material. There is no particular limitation on the insulating material; however, it is preferable that the insulating material has a high withstand voltage and forms a dense film. In addition, it is preferable that the insulating material has a high dielectric constant. For example, yttrium oxide, titanium oxide, aluminum oxide, hafnium oxide, tantalum oxide, barium titanate, strontium titanate, lead titanate, silicon nitride, zirconium oxide, or the like, or a mixed film or a layered film containing two or more of these materials can be used. The second dielectric layer 108 is formed from one or more of these materials, generally by using a wet process. For example, the second dielectric layer 108 in which light-scattering fine particles 106 are dispersed is formed using a droplet discharge method, a spin coating method, a dip coating method, a printing method, or the like.

The light-scattering fine particles 106 are formed of a material having a refractive index that is equal to or greater than that of the transmissive electrode 105. An organic or an inorganic material may be used. For example, an oxide of an element selected from zinc (Zn), indium (In), and tin (Sn) may be used, or a compound in which a dopant is added to such an oxide may be used. As dopants for zinc oxide, Al, Ga, B, and In are exemplified. Zinc oxides containing the aforementioned dopants are referred to as AZO, GZO, BZO, and IZO, respectively. Examples of dopants for indium oxide are Sn, Ti, and the like. Indium oxide doped with Sn is referred to as ITO (indium tin oxide). As dopants for tin oxide, Sb, F, and the like can be used. Further, metal oxides such as strontium oxide, aluminum oxide, titanium oxide, yttrium oxide, or cesium oxide can be employed. Moreover, various ferroelectric materials can be used. For example, metal oxide ferroelectric materials such as barium titanate, potassium niobate, and lithium niobate can be used. Further, an inorganic material such as silicon oxide, silicon nitride, silicon nitride oxide (SiNₓO_{y}, where 0<x< 4/3, 0<y<2, and 0<3x+2y≦4), zirconia, DLC (diamond-like carbon), or carbon nanotubes can be used. However, because the material is dispersed in the dielectric layer, a high dielectric material is preferably used.

It is necessary for the light-scattering fine particles 106 to be of a size (a particle diameter) where light having an incident angle such that it would be totally reflected at an interface between a dielectric layer and a transmissive electrode in a conventional structure can be refracted and scattered. Thus, the light can pass through the interface between the dielectric layer and the transmissive electrode. Specifically, the average size of the light-scattering fine particles 106 is 2 nm or more, more preferably, 20 nm or more. Further, the average size of the light-scattering fine particles 106 preferably does not exceed a wavelength in the visible light region, and is 800 nm at the most. Taking the optical design of the light-emitting element into consideration, the average size is preferably no more than 100 nm.

The light-scattering fine particles 106 are preferably shaped such that light is concentrated or scattered. For example, the fine particles may be column-shaped, polyhedral-shaped, or have a polygonal pyramid shape such as a trigonal pyramid shape. They may be conical-shaped, concave lens shaped, convex lens shaped, semi-cylindrical shaped, prism-shaped, spherically shaped, hemispherically shaped, and so on.

A plurality of light-scattering fine particles 106 are dispersed in the second dielectric layer 108. However, it is not necessary for all the light-scattering fine particles 106 to be formed from same material or to have the same size and shape. The light-scattering fine particles 106 may differ to one another in these respects.

The transmissive electrode 105 is formed over the second dielectric layer 108. The transmissive electrode 105 serves as an anode, and is an electrode through which light emitted from the light-emitting layer 104 passes. Light emitted from the light-emitting layer 104 passes through the second dielectric layer 108, or passes through the second dielectric layer 108 after being reflected by the reflective electrode, and is then extracted through the transmissive electrode 105.

The transmissive electrode 105 is formed from a transparent conductive film. A material which has a high transmittance with respect to light in the visible light region (400 to 800 nm) is used. Representatively, a metal oxide is used. For example, an oxide of an element including zinc (Zn), indium (In), and tin (Sn) may be used, or a compound in which a dopant is added to one of these oxides may be used. Examples of dopants for zinc oxide are Al, Ga, B, and In. Zinc oxides containing the aforementioned dopants are referred to as AZO, GZO, BZO, and IZO, respectively. Examples of dopants for indium oxide are Sn and Ti. Indium oxide doped with Sn is referred to as ITO (indium tin oxide). Examples of dopants for tin oxide are Sb, F. and the like. Further, as the transparent conductive film, it is possible to use a compound which is formed by mixing two or more oxides, selected from among zinc oxide, indium oxide, tin oxide, zinc oxide containing a dopant, indium oxide containing a dopant, and tin oxide containing a dopant.

Note that in this embodiment mode, the insulating layer 114, which covers a part of the reflective electrode 103, and the partition layer 115 are formed in order to separate the light-emitting elements 120. The insulating layer 114 can be formed using an inorganic insulating material, an organic insulating material, or the like, by a photolithography method and an etching method. There is no particular limitation on the material for the partition layer 115, but it is preferably formed by a photolithography method using a positive photosensitive resin whose unexposed parts remain, for example. In that case, a partition layer having a desirable angle of inclination can be formed by adjusting the amount of exposure or the developing time such that the lower part of the partition layer 115 is etched more rapidly. Of course, the partition wall 115 may also be formed by a photolithography method and an etching method using an inorganic insulating material, an organic insulating material, or the like.

Further, the height (the film thickness) of the partition layer 115 is more than the thicknesses of the first dielectric layer 107, the light-emitting layer 104, the second dielectric layer 108, and the transmissive electrode 105 combined. As a result, it is possible to fabricate the light-emitting elements 120 that are separated from each other into a plurality of electrically separated regions just by the process of forming the light-emitting layer 104, the second dielectric layer 108, and the transmissive electrode 105 over an entire surface of the substrate 101. Therefore, the number of processes can be reduced. Note that, over the partition layer 115, the first dielectric layer 157, the light-emitting layer 154, the second dielectric layer 158, and the transmissive electrode 155 are formed. However, they are separated from the first dielectric layer 107, the light-emitting layer 104, the second dielectric layer 108, and the transmissive electrode 105, which form the light-emitting elements 120.

In order to seal the light-emitting element 120, the substrate 112 is prepared. The uncured sealant 111 is provided at the periphery of the substrate 112. The uncured sealant 111 is provided in a predetermined shape at the periphery of the substrate 112, using a printing method, a dispenser method, or the like. Alternatively, the sealant 111 can be provided on the substrate 101 side after the formation of the transmissive electrode 105.

As the sealant 111, a photocurable resin which is curable by UV light or the like or a thermosetting resin can be used. For example, an epoxy resin or an acrylic resin can be used. Preferably, selection of either the photocurable resin or the thermosetting resin is made depending on the properties of the light-emitting layer 104.

The substrate 101 over which each of the layers is formed is put together with the substrate 112. The substrate 101 and the substrate 112 are firmly attached to one another by irradiating the uncured sealant 111 with UV light to cure the sealant 111 while applying pressure to the substrate 101 and the substrate 112. Of course, in a case where a thermosetting resin is used as the sealant 111, heat treatment is conducted. Further, from the time when the substrate 101 and the substrate 112 are put together until when the sealant 111 is cured, it is desirable to reduce the pressure of the atmosphere in which the treatment is conducted to some extent. Further, it is desirable to allow as little moisture as possible in the atmosphere in which the treatment is conducted. For example, the sealing process is preferably carried out under a nitrogen atmosphere.

The space between the substrate 101 and the substrate 112 is made airtight by curing the sealant 111, and is filled with the gas 113.

After sealing the substrate 101 with the substrate 112, the substrate 112 is divided into panels of a desired size.

In this embodiment mode, by dispersing many light-scattering fine particles 106 in the second dielectric layer 108 which is provided between the transmissive electrode 105 and the light-emitting layer 104, the efficiency of light extraction from the light-emitting element 120 can be improved. This is because when light emitted from the light-emitting layer 104 transmits through the second dielectric layer 108, the light is refracted and scattered by the light-scattering fine particles 106, and the incident angle of the light varies depending on the place. Therefore, light having an incident angle, which would cause it to totally reflect at the interface between the second dielectric layer 108 and the transmissive electrode 105 in a conventional structure, can pass through. A feature of the invention is to improve the light extraction efficiency of the light-emitting element 120 in this manner, by dispersing light-scattering fine particles 106 in the second dielectric layer 108 so that the amount of light that is totally reflected at the interface between the second dielectric layer 108 and the transmissive electrode 105 is reduced.

Note that Reference 1 describes improving light extraction efficiency by providing a particle-containing transparent electrode layer, in which fine particles are dispersed, over a transparent electrode layer. That is, in Reference 1, by scattering light using fine particles in a particle-containing transparent electrode layer, an angle of the light is changed to an angle at which total reflection does not occur, and thereby extraction efficiency is improved. Meanwhile, in the invention proposed in this specification, light extraction efficiency is improved by changing the incident angle of light upon the interface of the transparent electrode 105 using light-scattering fine particles 106 that are dispersed in the second dielectric layer 108 located between the transmissive electrode 105 and the light-emitting layer 104. Thus, the invention disclosed in this specification is completely different from that in Reference 1.

Since the light-emitting element of this embodiment mode can reduce the amount of light emitted from the light-emitting layer that is totally reflected at the interface between the transmissive electrode and the dielectric layer, the efficiency of light extraction to the outside can be improved.

Further, a display device of this embodiment mode includes the light-emitting element with high light extraction efficiency. Therefore, the display device has high luminance and low power consumption.

### Embodiment Mode 2

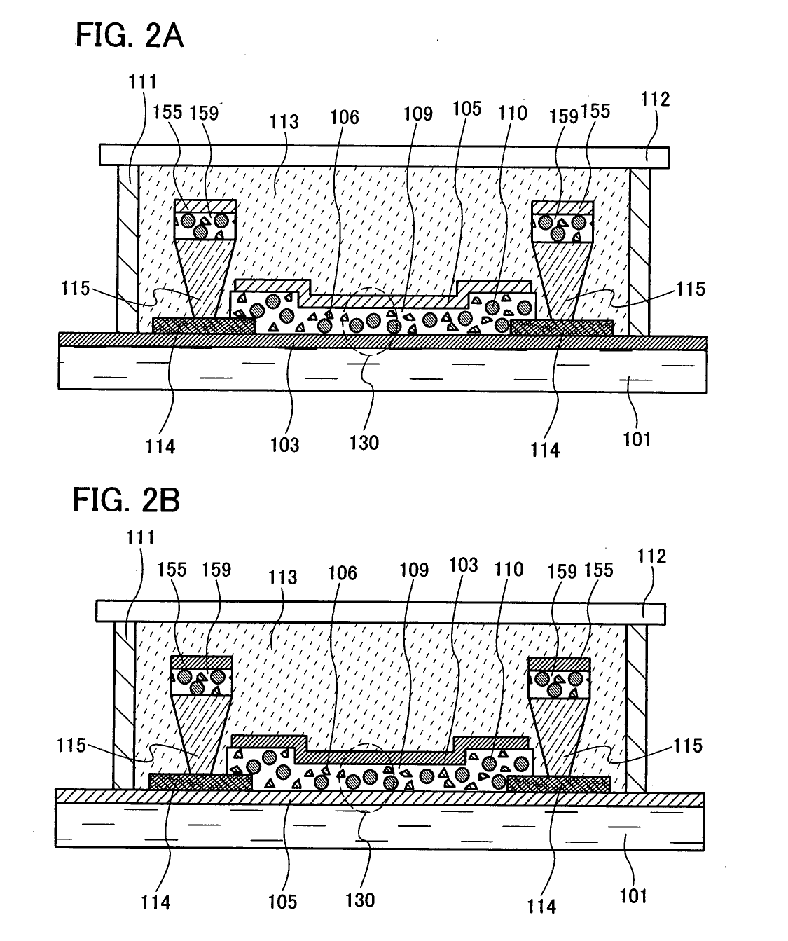

In this embodiment mode, a mode in which the present invention is applied to a dispersion-type inorganic light-emitting element which is one of the light-emitting elements is described. FIG. 2A shows a cross section of a display device employing a top emission structure. FIG. 2B shows a cross section of a display device employing a bottom emission structure. FIGS. 2A and 2B differ in structure only in that the positions and order of formation of the reflective electrode 103 and the transmissive electrode 105 are reversed. Therefore, unless specific description is given, description will be made with reference to the top emission structure shown in FIG. 2A.

In Embodiment Mode 1, a structure was described in which the light-emitting element 120 is formed between the substrate 101 and the substrate 112, and the light-emitting element 120 includes the reflective electrode 103, the first dielectric layer 107, the light-emitting layer 104, the second dielectric layer 108 in which light-scattering fine particles 106 are dispersed, and the transmissive electrode 105. This embodiment mode differs from Embodiment Mode 1 in that it employs the so-called dispersion-type inorganic light-emitting element in which the first dielectric layer 107, the light-emitting layer 104, and the second dielectric layer 108 dispersed with the light-scattering fine particles 106 are integrated into one layer. That is, a light-emitting element 130 described in this embodiment mode includes a light-emitting layer 109 interposed between the reflective electrode 103 and the transmissive electrode 105, and particles of light-emitting material 110 and light-scattering fine particles 106 are dispersed in the light-emitting layer 109.

First, a substrate 101 over which the reflective electrode 103 is formed is prepared, according to processes described in Embodiment Mode 1.

Next, the light-emitting layer 109 is formed over the reflective electrode 103. The light-emitting layer 109 is a layer in which particles of a light-emitting material 110 are dispersed in a binder. Further, light-scattering fine particles 106 are also dispersed in the binder in the light-emitting layer 109. The binder is a material for fixing the dispersed particles of light-emitting material and maintaining the shape of the light-emitting layer. The particles of light-emitting material 110 are dispersed evenly throughout the light-emitting layer and fixed in place by the binder.

A light-emitting material described in Embodiment Mode 1 can be processed into particles which can be used as the particles of light-emitting material 110. When a desired size of particle cannot be sufficiently obtained depending on a preparation method of the light-emitting material, the light-emitting materials may be processed into particles by crushing in a mortar or the like.

Further, as the light-scattering fine particles 106, the light-scattering fine particles 106 described in Embodiment Mode 1 can be used.

As the binder used in the light-emitting layer 109, an organic material or an inorganic material can be used. A mixed material containing an organic material and an inorganic material may also be used. As an organic material, the following resin materials can be used: a polymer with a relatively high dielectric constant such as a cyanoethyl cellulose-based resin, or a resin such as polyethylene, polypropylene, a polystyrene-based resin, a silicone resin, an epoxy resin, poly(vinylidene fluoride) resin, or the like. Further, a heat-resistant high molecular weight material such as aromatic polyamide or polybenzimidazole, or a siloxane resin may also be used. A siloxane resin is a resin including a Si—O—Si bond. Siloxane is a material which has a backbone formed of bonds between silicon (Si) and oxygen (O). As a substitutent, an organic group containing at least hydrogen (for example, an alkyl group or an aromatic hydrocarbon) can be used. Alternatively, a fluorine may be used as a substitutent. Further alternatively, both a fluorine and an organic group containing at least hydrogen may be used as a substitutent. Further, the following resin materials may also be used: a vinyl resin such as polyvinyl alcohol or polyvinylbutyral, a phenol resin, a novolac resin, an acrylic resin, a melamine resin, a urethane resin, an oxazole resin (e.g., polybenzoxazole), or the like. Fine particles with a high dielectric constant such as particles of barium titanate or strontium titanate can be mixed with these resins appropriately to adjust the dielectric constant.

The inorganic material can be formed using silicon nitride (SiNₓ), silicon containing oxygen and nitrogen, aluminum nitride, aluminum containing oxygen and nitrogen, aluminum oxide, titanium oxide, barium titanate, strontium titanate, lead titanate, potassium niobate, lead niobate, tantalum oxide, barium tantalate, lithium tantalate, yttrium oxide, zirconium oxide, zinc sulfide, or other substances containing an inorganic material. By including an inorganic material with a high dielectric constant in the organic material, the dielectric constant of the light-emitting layer 109 including the binder in which particles of light-emitting material 110 are dispersed can be further controlled, and the dielectric constant can be further increased.

In the fabrication process, the particles of light-emitting material 110 are dispersed in a solution containing a binder. As a solvent for the solution containing a binder that can be used in this embodiment mode, a solvent in which the binder material dissolves and which can form a solution with a viscosity that is suitable for the method of forming the light-emitting layer (the various wet processes) and for a desired film thickness may be selected appropriately. An organic solvent or the like can be used as such a solvent. For example, when a siloxane resin is used as the binder, propylene glycolmonomethyl ether, propylene glycolmonomethyl ether acetate (also called PGMEA), 3-methoxy-3-methyl-1-butanol (also called MMB), or the like can be used as the solvent.

The light-emitting element 130 of this embodiment mode is a dispersion-type inorganic light-emitting element, and the light-emitting layer 109 is a layer in which a plurality of particles of light-emitting material 110 and the light-scattering fine particles 106 are dispersed in a binder. As a method of forming the light-emitting layer 109, wet processes can be mainly used. For example, a droplet discharge method, a printing method (screen-printing, offset printing, or the like), a coating method such as a spin coating method, a dipping method, a dispenser method, or the like can be used. Further, the weight percent of the particles of light-emitting material 110 in the light-emitting layer 109 is preferably greater than or equal to 50 weight percent and less than or equal to 80 weight percent.

Over the light-emitting layer 109, the transmissive electrode 105 is formed using a material described in Embodiment Mode 1. Further, as in Embodiment Mode 1, over the reflective electrode 103, the insulating layer 114, which covers part of the reflective electrode 103, and the partition layer 115 are formed. Note that a separated light-emitting layer 159 and transmissive electrode 155 are layered over the partition layer 115. After the transmissive electrode 105 is formed, the substrate 101 and the substrate 112 are firmly attached to each other according to processes described in Embodiment Mode 1, and the substrate 112 is divided into panels of a desired size.

In this embodiment mode, by dispersing many light-scattering fine particles 106 in the light-emitting layer 109, the extraction efficiency of light from the light-emitting element 130 can be improved. This is because when light generated from the particles of light-emitting material 110 dispersed in the light-emitting layer 109 passes through the light-emitting layer 109, the light is refracted and scattered by the light-scattering fine particles 106, and the incident angle of the light varies depending on the place. Therefore, light having an incident angle which causes it to totally reflected at the interface between the light-emitting layer 109 and the transmissive electrode 105 in the absence of light-scattering fine particles, can pass through. That is, light having an incident angle such that it would be totally reflected by the transmissive electrode 105 in the absence of light-scattering fine particles 106, can pass through the transmissive electrode 105. A feature of the invention is that the light extraction efficiency of the light-emitting element 130 is improved by dispersing the light-scattering fine particles 106 in the light-emitting layer 109. Thus, the amount of light emitted from the particles of light-emitting material 110, which are also dispersed in the light-emitting layer 109, that is totally reflected at the interface with the transmissive electrode 105 is reduced.

In this way, a light-emitting element of this embodiment mode can increase the efficiency of light extraction to the outside. Further, since a display device of this embodiment mode includes the light-emitting element having high light extraction efficiency, it has high luminance and low power consumption.

### Embodiment Mode 3

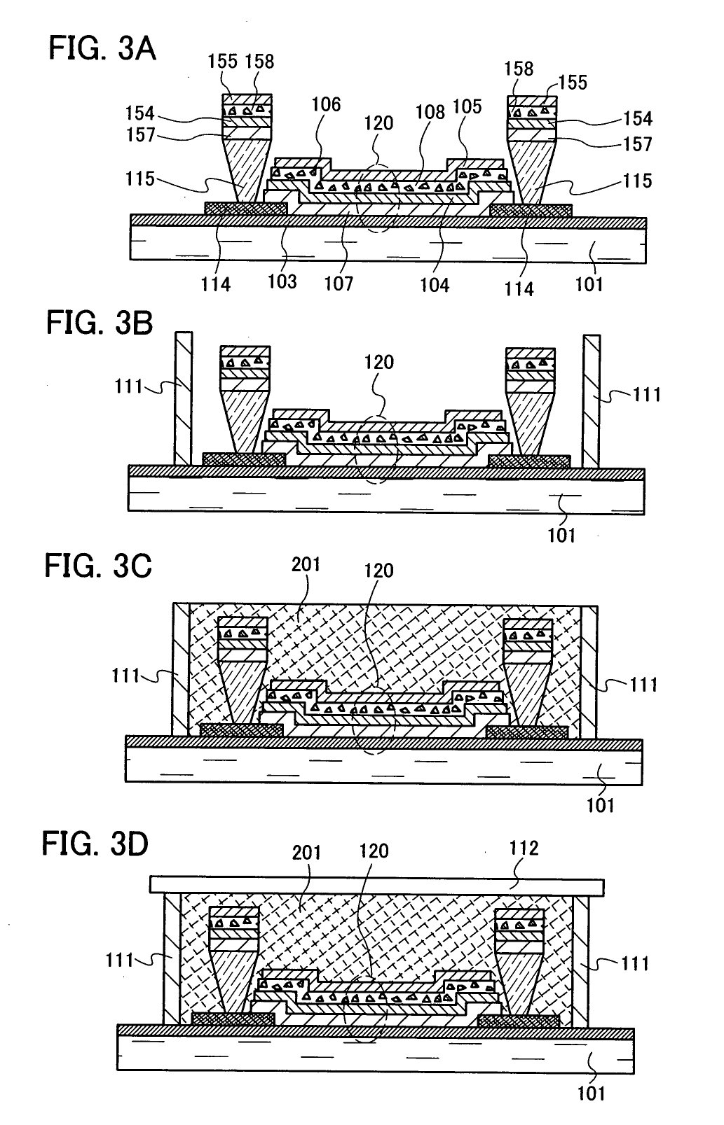

This embodiment mode will be described with reference to FIGS. 3A to 3D. In Embodiment Mode 1, the airtight space between the substrate 101 and the substrate 112 is filled with the gas 113. However, in a display device of this embodiment mode, the space is filled with a liquid phase material, and the liquid phase material is then cured to form a solid which fills the space. A sealing structure of a display device in which a solid is provided between a pair of substrates in this way is referred to as a solid sealed structure. This term is sometimes used to make a distinction from structures in which a gas fills the space. In this specification, this term will be used to make a distinction from the structures in which the space is filled with a gas.

A substrate over which the elements up to and including the transmissive electrode 105 are formed is prepared according to processes described in Embodiment Mode 1 (FIG. 3A). Further, as in Embodiment Mode 1, over the reflective electrode 103, the insulating layer 114, which covers part of the reflective electrode 103, and the partition layer 115 are formed. Note that over the partition layer 115, the separated first dielectric layer 157, light-emitting layer 154, second dielectric layer 158, and transmissive electrode 155 are layered.

Next, as in Embodiment Mode 1, the uncured sealant 111 is provided in a predetermined shape at the periphery of the substrate 101, using a printing method, a dispenser method, or the like (FIG. 3B).

In this embodiment mode, a filler 201 is provided in a space between the substrate 101 and the substrate 112 that is made airtight by the sealant 111. As a material for the filler 201, a UV curable resin, a visible light curable resin, or a thermosetting resin can be used. For example, an epoxy resin or an acrylic resin can be used. Selection of either a UV curable resin, a visible light curable resin, or a thermosetting resin is made taking a heat resistance property of a material of the light-emitting layer 104 into consideration. After the sealant 111 is provided, the uncured (liquid phase) filler 201 is added dropwise into the region surrounded by the sealant 111 (FIG. 3C).

Next, the substrate 112 is placed on the substrate 101 which is provided with the uncured sealant 111 and the filler 201. While applying pressure to the substrate 101 and the substrate 112, the uncured sealant 111 and the filler 201 are each cured by being irradiated with light or by heating. Thereby, the substrate 112 is firmly attached to the substrate 101. The cured filler 201 is provided so as to be in contact with a surface of the transmissive electrode 105 and a surface of the substrate 101, so the substrate 112 is secured to the substrate 101. After the sealant 111 and the filler 201 are cured, the substrate 112 is divided into panels of a desired size (FIG. 3D).

A light-emitting element of this embodiment mode has high light extraction efficiency. Therefore, a display device including such a light-emitting element has high luminance and low power consumption. Further, a display device of this embodiment mode is formed with a solid sealed structure in which the space is filled with a liquid phase material, and the liquid phase material is then cured. Therefore, it is possible to seal the light-emitting element by sealing up the space between the pair of substrates leaving no space, so that water vapor and the like can be prevented from penetrating the light-emitting element. Thus, deterioration of the light-emitting element can be prevented.

Note that in this embodiment mode, description was made with reference to the case of a top emission structure; however, a bottom emission structure can also be employed. In a case where a bottom emission structure is employed in the structure illustrated in FIGS. 3A to 3D, the invention can be achieved by reversing the positions and order of formation of the reflective electrode 103 and the transmissive electrode 105 and of the first dielectric layer 107 and the second dielectric layer 108.

### Embodiment Mode 4

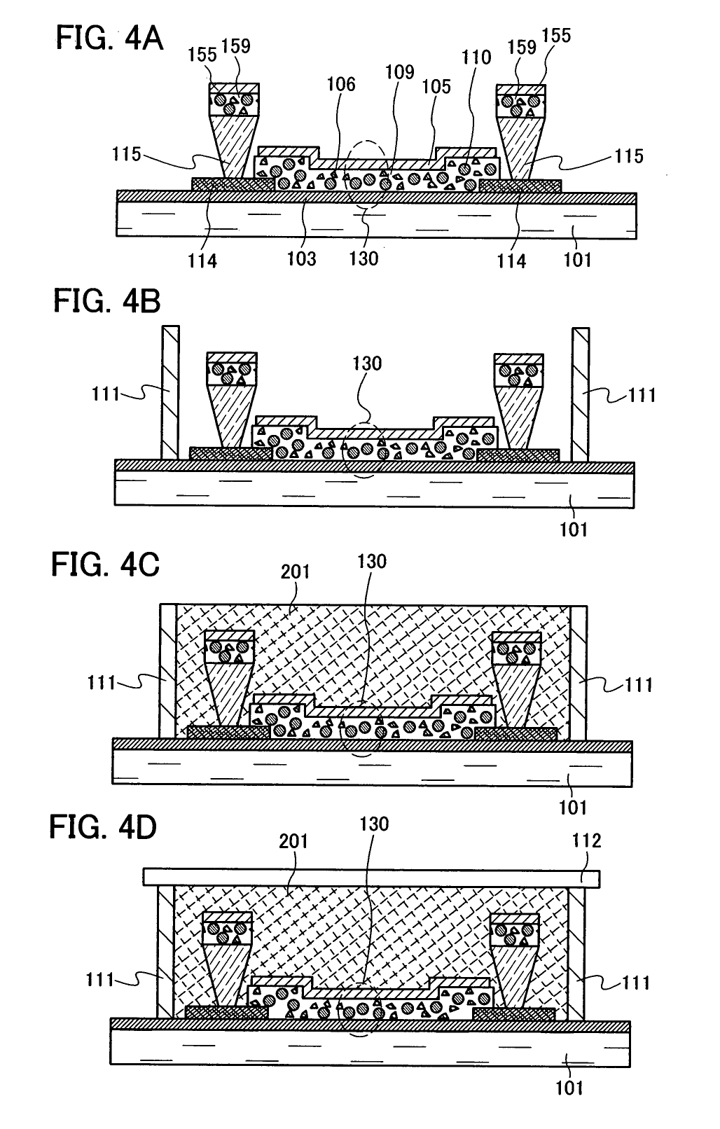

This embodiment mode will be described with reference to FIGS. 4A to 4D. In Embodiment Mode 2, an airtight space between the substrate 101 and the substrate 112 was filled with the gas 113. However, in a display device of this embodiment mode, the space is filled with a liquid phase material, and the liquid phase material is then cured to form a solid which fills the space.

A substrate over which elements up to and including the transmissive electrode 105 are formed is prepared according to processes described in Embodiment Mode 2 (FIG. 4A). Further, as in Embodiment Mode 2, over the reflective electrode 103, the insulating layer 114, which covers part of the reflective electrode 103, and the partition layer 115 are formed. Note that the separated light-emitting layer 159 and transmissive electrode 155 are layered over the partition layer 115.

Next, according to processes described in Embodiment Mode 3, the sealant 111 is provided at the periphery of the substrate 101 (FIG. 4B), and the filler 201 is provided (FIG. 4C). Subsequently, the substrate 101 and the substrate 112 are firmly attached to one another, and the substrate 112 is divided into panels of a desired size (FIG. 4D).

A light-emitting element of this embodiment mode has high light extraction efficiency. Thus, a display device including such a light-emitting element can realize high luminance and low power consumption. Further, the display device of this embodiment mode is formed with a solid sealed structure in which a space is filled with a liquid phase material, and the liquid phase material that has filled the space is then cured. Therefore, it is possible to seal the light-emitting element by sealing up the space between the pair of substrates leaving no space, so that water vapor and the like can be prevented from penetrating the light-emitting element. Therefore, deterioration of the light-emitting element can be suppressed.

Note that in this embodiment mode, description was made with reference to the case of a top emission structure; however, a bottom emission structure can also be employed. In a case where a bottom emission structure is employed in the structure illustrated in FIGS. 4A to 4D, the positions and order of formation of the reflective electrode 103 and the transmissive electrode 105 are reversed.

### Embodiment Mode 5

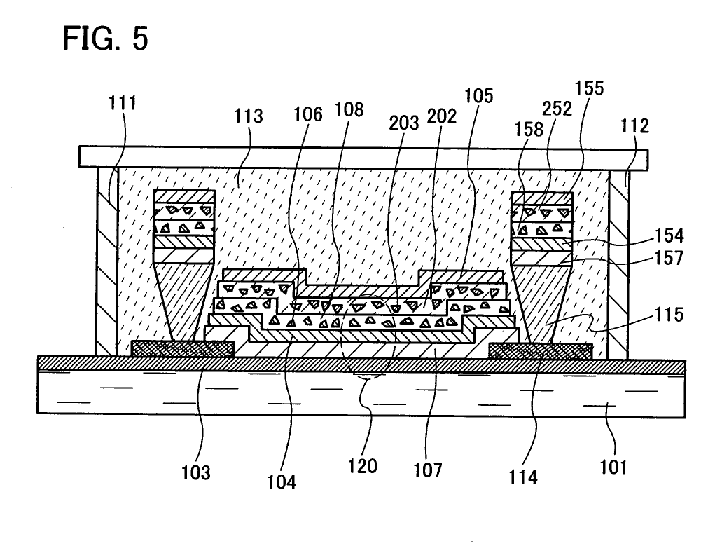

This embodiment mode will be described with reference to FIG. 5. The structure of this embodiment mode is basically the same as that of Embodiment Mode 1 (FIG. 1A), except that a third dielectric layer 202 is added.

Elements including the second dielectric layer 108 in which light-scattering fine particles 106 are dispersed are formed over the substrate 101, according to processes described in Embodiment Mode 1. Next, the third dielectric layer 202 in which light-scattering fine particles 203 are dispersed is formed over the second dielectric layer 108.

The transmissive electrode 105 is formed over the third dielectric layer 202. Further, as in Embodiment Mode 1, over the reflective electrode 103, the insulating layer 114, which covers part of the reflective electrode 103, and the partition layer 115 are formed. Note that over the partition layer 115, the separated first dielectric layer 157, light-emitting layer 154, second dielectric layer 158, third dielectric layer 252, and transmissive electrode 155 are layered. After the transmissive electrode 105 is formed, as in Embodiment Mode 1, the substrate 101 and the substrate 112 are firmly attached to one another, and the substrate 112 is divided into panels of a desired size.

For the light-scattering fine particles 106, a material with a high dielectric constant, high insulation properties and a low refractive index is used. For example, particles of silicon dioxide (silica) or the like can be used as the light-scattering fine particles 106. To compensate for the low refractive index of the light-scattering fine particles 106, it is preferable to use a material with a high refractive index for the light-scattering fine particles 203 which are dispersed in the third dielectric layer 202. Even materials with a low dielectric constant and low insulating properties can be used for the light-scattering fine particles 203, as long as the light-scattering fine particles 203 have a high refractive index. For example, particles of ITO or the like can be used as the light-scattering fine particles 203. In this embodiment mode, by forming the dielectric layer provided between the transmissive electrode and the light-emitting layer as a two-layer structure which includes the second dielectric layer 108 and the third dielectric layer 202, a dielectric layer with a desired dielectric constant, insulating property, and refractive index can be obtained.

Further, the third dielectric layer 202 can be formed using the same materials as those that can be used for the second dielectric layer 108. That is, the third dielectric layer 202 is formed from an insulating material. There is no particular limitation on the insulating material used for the third dielectric layer 202. However, preferably the insulating material has a high withstand voltage and forms a dense film. In addition, preferably it has a high dielectric constant. For example, yttrium oxide, titanium oxide, aluminum oxide, hafnium oxide, tantalum oxide, barium titanate, strontium titanate, lead titanate, silicon nitride, zirconium oxide, or the like, or a mixed film or a layered film containing two or more of these materials can be used. The third dielectric layer 202 is formed from one or more of these materials, generally by using a wet process. For example, the third dielectric layer 202 in which light-scattering fine particles 203 are dispersed is formed using a droplet discharge method, a spin coating method, a dip coating method, a printing method, or the like. Note that in this embodiment mode, a two-layer structure including the second dielectric layer 108 in which light-scattering fine particles 106 are dispersed and the third dielectric layer 202 in which light-scattering fine particles 203 are dispersed is employed; however, a dielectric layer with three or more layers may be provided. As shown in this embodiment mode, a dielectric constant can be adjusted to a desired value by forming the dielectric layer provided between the transmissive electrode 105 and the light-emitting layer 104 as a plurality of layers including two or more layers. Accordingly, electrical energy of a sufficient magnitude can be applied to the light-emitting layer, and stable light emission can be obtained.

Further, in this embodiment mode, the structure shown in FIG. 1A of Embodiment Mode 1 is used as a basis; however, the structure shown in FIG. 1B of Embodiment Mode 1 may also be used. That is, the positions and order of formation of the reflective electrode 103 and the transmissive electrode 105 and of the first dielectric layer 107 and the second dielectric layer 108 may be reversed, and the third dielectric layer 202 in which light-scattering fine particles 203 are dispersed may be provided between the transmissive electrode 105 and the second dielectric layer 108.

A light-emitting element of this embodiment mode has improved efficiency of light extraction to the outside. A display device including such a light-emitting element can realize high luminance and low power consumption.

Further, in a light-emitting element of this embodiment mode, a dielectric constant can be adjusted to a desired level by forming the dielectric layer as a stacked structure, enabling stable light emission. Further, since a display device of this embodiment mode includes the light-emitting element which is capable of stable light emission, increase in luminance can be readily achieved.

### Embodiment Mode 6

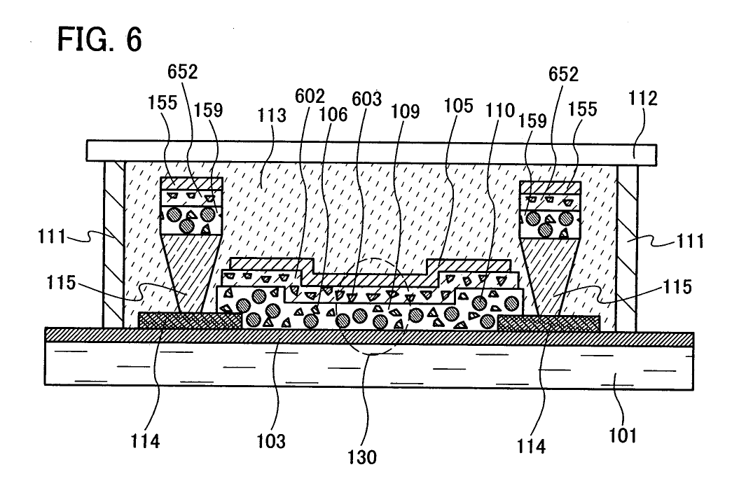

This embodiment mode will be described with reference to FIG. 6. This embodiment mode has basically the same structure as that in FIG. 2A of Embodiment Mode 2, with the addition of a dielectric layer 602.

Elements including the light-emitting layer 109 in which the particles of light-emitting material 110 and the light-scattering fine particles 106 are dispersed are formed over the substrate 101, according to processes described in Embodiment Mode 2. Next, the dielectric layer 602 in which light-scattering fine particles 603 are dispersed is formed over the light-emitting layer 109.

The transmissive electrode 105 is formed over the dielectric layer 602. Further, as in Embodiment Mode 2, over the reflective electrode 103, the insulating layer 114, which covers part of the reflective electrode 103, and the partition layer 115 are formed. Note that over the partition layer 115, the separated light-emitting layer 159, dielectric layer 652, and transmissive electrode 155 are layered. After the transmissive electrode 105 is formed, process steps the same as those in Embodiment Mode 2, including the attachment of the substrate 101 to the substrate 112, are carried out. The substrate 112 is divided into panels of a desired size.

For the light-scattering fine particles 106, a material with a high dielectric constant, high insulation properties and a low refractive index is used. For example, particles of silicon dioxide (silica) or the like can be used as the light-scattering fine particles 106. To compensate for the low refractive index of the light-scattering fine particles 106, it is preferable to use a material with a high refractive index for the light-scattering fine particles 603 which are dispersed in the dielectric layer 602. A material with a low dielectric constant and low insulating properties can be used for the light-scattering fine particles 603, as long as the material has a high refractive index. For example, particles of ITO or the like can be used as the light-scattering fine particles 603. Fabrication of the dielectric layer of this embodiment mode as a two-layered structure by using the light-emitting layer 109 and the dielectric layer 602 enables the formation of the dielectric layer with a desired dielectric constant, insulating property, and refractive index.

The dielectric layer 602 is formed from an insulating material. Although there is no particular limitation, the insulating material preferably has a high withstand voltage and forms a dense film. In addition, preferably it has a high dielectric constant. For example, yttrium oxide, titanium oxide, aluminum oxide, hafnium oxide, tantalum oxide, barium titanate, strontium titanate, lead titanate, silicon nitride, zirconium oxide, or the like, or a mixed film or a layered film containing two or more of these materials can be used. The dielectric layer 602 is formed from one or more of these materials, generally by using a wet process. For example, the dielectric layer 602 in which light-scattering fine particles 603 are dispersed is formed using a droplet discharge method, a spin coating method, a dip coating method, a printing method, or the like. Note that the dielectric layer 602 may be formed as a stacked structure including two or more layers. As shown in this embodiment mode, the dielectric constant of the dielectric layer can be adjusted to a desired level by providing the dielectric layer 602 between the transmissive electrode 105 and the light-emitting layer 109. Accordingly, electrical energy of a sufficient magnitude can be applied to the light-emitting layer, and stable light emission can be obtained.

Further, in this embodiment mode, the structure shown in FIG. 2A of Embodiment Mode 2 is used as a basis; however, the structure shown in FIG. 2B of Embodiment Mode 2 may also be used. That is, the positions and order of formation of the reflective electrode 103 and the transmissive electrode 105 may be reversed, and the dielectric layer 602 in which light-scattering fine particles 603 are dispersed may be provided between the transmissive electrode 105 and the light-emitting layer 109.

A light-emitting element of this embodiment mode possesses improved efficiency of light extraction to the outside. A display device including such a light-emitting element can realize high luminance and low power consumption.

Further, in a light-emitting element of this embodiment mode, a dielectric constant can be adjusted to a desired level by forming the dielectric layer as a stacked structure, thus stable light emission can be obtained. Further, since a display device of this embodiment mode includes the light-emitting element which is capable of stable light emission, increase in luminance can be readily achieved.

### Embodiment Mode 7

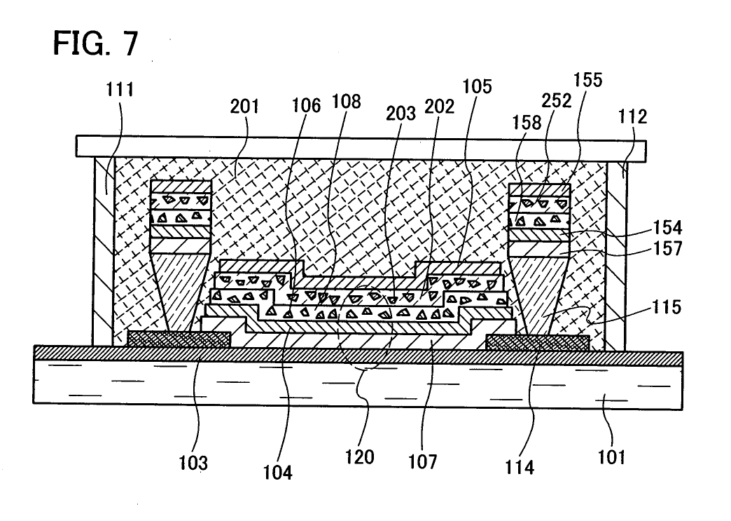

This embodiment mode is illustrated in FIG. 7. Like Embodiment Mode 3, this embodiment mode employs a solid sealed structure. The difference between this Embodiment Mode and Embodiment Mode 3 is that the third dielectric layer 202, in which light-scattering fine particles 203 are dispersed, is formed between the transmissive electrode 105 and the second dielectric layer 108 in which light-scattering fine particles 106 are dispersed.

Elements including the second dielectric layer 108 in which the light-scattering fine particles 106 are dispersed are formed over the substrate 101, according to the processes described in Embodiment Mode 3. Next, the third dielectric layer 202 in which the light-scattering fine particles 203 are dispersed is formed over the second dielectric layer 108. The light-scattering fine particles 203 and the third dielectric layer 202 can be formed using the materials and manufacturing methods described in Embodiment Mode 5.

Next, the transmissive electrode 105 is formed over the third dielectric layer 202. Further, as described in Embodiment Mode 3, over the reflective electrode 103, the insulating layer 114, which covers part of the reflective electrode 103, and the partition layer 115 are formed. Note that over the partition layer 115, the separated first dielectric layer 157, light-emitting layer 154, second dielectric layer 158, third dielectric layer 252, and transmissive electrode 155 are layered. After the transmissive electrode 105 is formed, the substrate 101 and the substrate 112 are firmly attached to one another using the sealant 111 and the filler 201 according to the process described in Embodiment Mode 3.

A light-emitting element of this embodiment mode has high light extraction efficiency and is capable of stable light emission. A display device including such a light-emitting element exhibits high luminance and low power consumption.

### Embodiment Mode 8

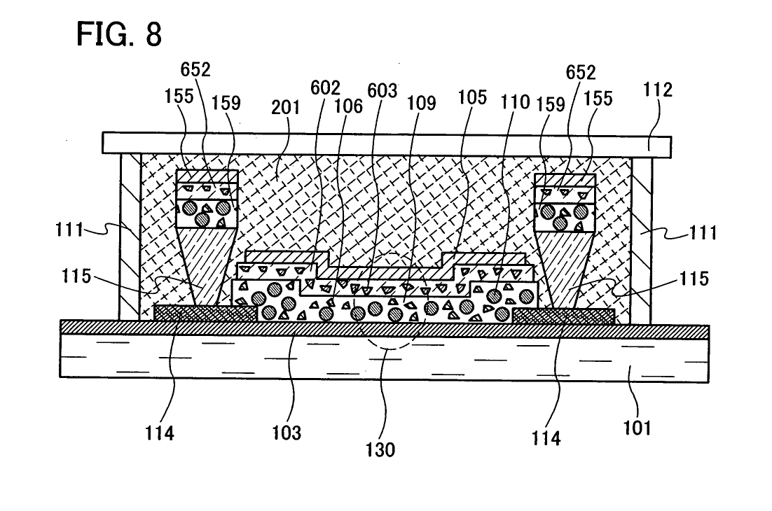

This embodiment mode is illustrated in FIG. 8. Like Embodiment Mode 4, this embodiment mode employs a solid sealed structure. The difference between this Embodiment Mode and Embodiment Mode 4 is that the dielectric layer 602 in which the light-scattering fine particles 603 are dispersed is formed between the transmissive electrode 105 and the light-emitting layer 109 in which the particles of light-emitting material 110 and the light-scattering fine particles 106 are dispersed.

Elements including the light-emitting layer 109 in which the particles of light-emitting material 110 and the light-scattering fine particles 106 are dispersed are formed over the substrate 101 according to the process described in Embodiment Mode 4. Next, the dielectric layer 602 in which the light-scattering fine particles 603 are dispersed is formed over the light-emitting layer 109. The light-scattering fine particles 603 and the dielectric layer 602 can be formed using the materials and manufacturing methods described in Embodiment Mode 6.

Next, the transmissive electrode 105 is formed over the dielectric layer 602. Further, as shown in Embodiment Mode 4, over the reflective electrode 103, the insulating layer 114, which covers part of the reflective electrode 103, and the partition layer 115 are formed. Note that over the partition layer 115, the separated light-emitting layer 159, dielectric layer 652, and transmissive electrode 155 are layered. After the transmissive electrode 105 is formed, the substrate 101 and the substrate 112 are firmly attached to one another using the sealant 111 and the filler 201 according to the process described in Embodiment Mode 4.

A light-emitting element of this embodiment mode has high light extraction efficiency and is capable of stable light emission. A display device including such a light-emitting element demonstrates high luminance and low power consumption.

### Embodiment Mode 9

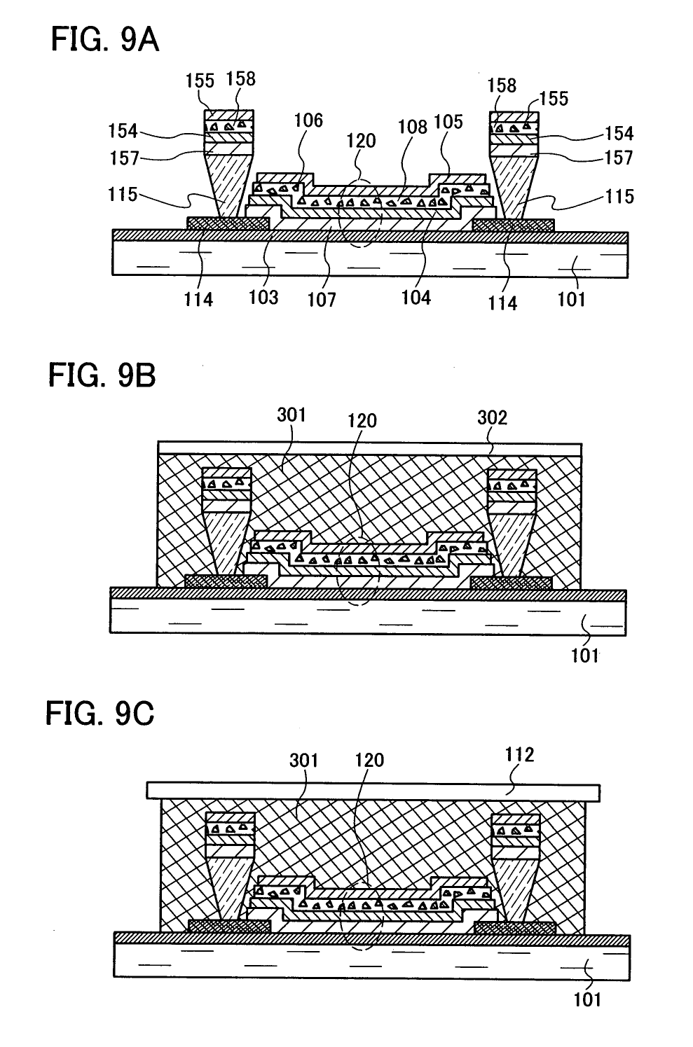

Embodiment Mode 9 is illustrated in FIGS. 9A to 9C. This embodiment mode is a display device with a solid sealed structure. In Embodiment Modes 3, 4, 7, and 8, a solid sealed structure was described in which a solid obtained by curing the liquid phase material is provided. In this Embodiment Mode 9, a solid sealed structure employing a solid prepared by curing a sheet-like sealant (also called a film sealant) provided over a film support is demonstrated.

Elements up to and including the transmissive electrode 105 are formed over the substrate 101 according to processes described in Embodiment Mode 1 (FIG. 9A). Further, as in Embodiment Mode 1, over the reflective electrode 103, the insulating layer 114, which covers part of the reflective electrode 103, and the partition layer 115 are formed. Note that over the partition layer 115, the separated first dielectric layer 157, light-emitting layer 154, second dielectric layer 158, and transmissive electrode 155 are layered.

In order to attach the substrate 112 to the substrate 101, a sheet-like sealant 301 is prepared. The uncured sheet-like sealant 301 is formed of a resin material with an adhesive function. As the sheet-like sealant 301, a UV curable resin, a visible light curable resin, or a thermosetting resin can be used. To protect the adhesive surface, both surfaces of the sealant 301 are covered with film support 302. The film support 302 on one surface of the sheet-like sealant 301 is peeled off, and then that surface of the sheet-like sealant 301 is placed on a surface of the substrate 101 (FIG. 9B).

Next, the remaining film support 302 is peeled off, and the substrate 112 is placed on the substrate 101. The substrate 112 is firmly attached to the substrate 101 by curing the sheet-like sealant 301, which is carried out by irradiating with UV light or heating, while applying pressure to the substrate 101 and the substrate 112 (FIG. 9C).

By using the sheet-like sealant 301 in this manner, the substrate 112 can be easily attached to the substrate 101, and a display device with a solid sealed structure can be formed.

Note that, in the process shown in FIG. 9B, the sheet-like sealant 301 can be provided on the sealing substrate 112 instead of the substrate 101. That is, the film support 302 on one surface of the sheet-like sealant 301 may be peeled off, then after placing the exposed surface of the sheet-like sealant 301 onyo a surface of the substrate 112, the film support 302 on the other surface of the sheet-like sealant 301 may be peeled off. Then, the substrate 101 may be placed on the substrate 112.

A light-emitting element of this embodiment mode has high light extraction efficiency, and a display device including such a light-emitting element can show high luminance and low power consumption. Further, by using a sheet-like sealant, the substrates can be easily attached to each other and the light-emitting element can be readily sealed.

### Embodiment Mode 1

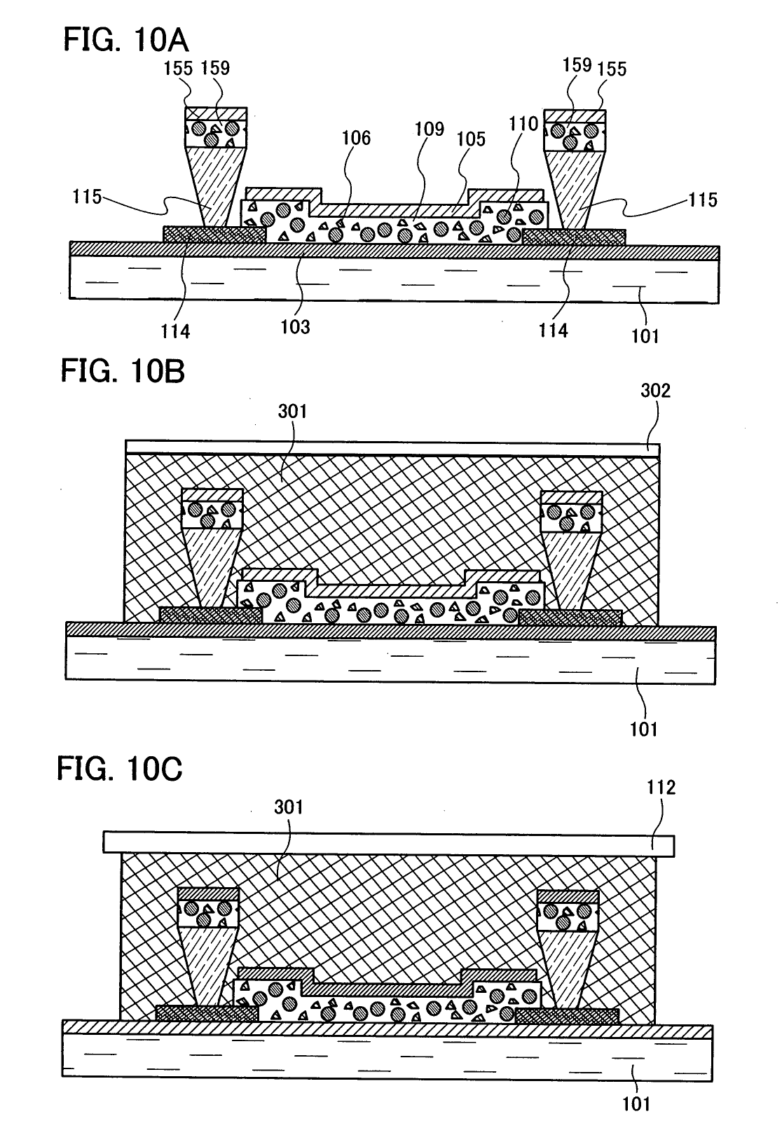

This embodiment will be described with reference to FIGS. 10A to 10C. Like Embodiment Mode 9, this embodiment mode employs a solid sealed structure which uses a solid that is an uncured sheet-like sealant.

Elements up to and including the transmissive electrode 105 are formed over the substrate 101 according to processes described in Embodiment Mode 2 (FIG. 10A). Further, as in Embodiment Mode 2, over the reflective electrode 103, the insulating layer 114, which covers part of the reflective electrode 103, and the partition layer 115 are formed. Note that over the partition layer 115, the separated light-emitting layer 159 and transmissive electrode 155 are layered.

In order to attach the substrate 112 to the substrate 101, the sheet-like sealant 301 is prepared. The sealant 301 is the same as that in Embodiment Mode 9, and both surfaces of the sealant 301 are covered with the film support 302. Then, according to processes described in Embodiment Mode 9, the film support 302 on one surface of the sheet-like sealant 301 is peeled off, and that surface of the sheet-like sealant 301 is placed on a surface of the substrate 101 (FIG. 10B).

The remaining film support 302 is peeled off, and the substrate 112 is placed on the substrate 101. The substrate 112 is firmly attached to the substrate 101 by curing the sheet-like sealant 301, which is performed by being irradiated with UV light or heating while applying pressure to the substrate 101 and the substrate 112 (FIG. 10C).

By using the sheet-like sealant 301 in this manner, the substrate 112 can be easily attached to the substrate 101, and a display device with a solid sealed structure can be fabricated.

Note that in the process shown in FIG. 10B, the sheet-like sealant 301 can be provided on the sealing substrate 112 side instead of the substrate 101 side. That is, the film support 302 on one surface of the sheet-like sealant 301 may be peeled off, then after placing that surface of the sheet-like sealant 301 onto a surface of the substrate 112, the film support 302 on the other surface of the sheet-like sealant 301 may be peeled off. Then, the substrate 101 may be placed on the substrate 112.

A light-emitting element of this embodiment mode has high light extraction efficiency, and a display device including such a light-emitting element can realize high luminance and low power consumption. Further, by using a sheet-like sealant, the substrates can be easily attached to each other, and the light-emitting element can be easily sealed.

### Embodiment Mode 11

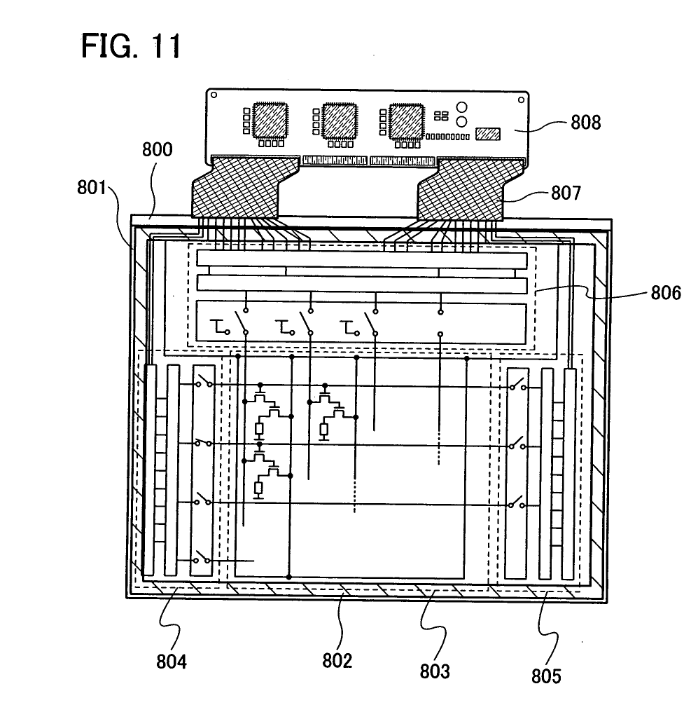

This embodiment mode will be described with reference to FIGS. 11 to 14 and FIGS. 17A and 17B. In this embodiment mode, an example of using an active matrix EL panel having a display function will be described.

FIG. 11 is a top schematic diagram of an active matrix EL panel. A sealing substrate 801 is firmly fixed to a substrate 800 by a sealant 802, and a space between the substrate 800 and the substrate 801 is airtight. Further, in this embodiment mode, the sealing structure of the EL panel is a solid sealed structure, and the space is filled with a filler formed of resin.

Over the substrate 800, a pixel portion 803, a gate signal line driver circuit portion for writing 804, a gate signal line driver circuit portion for erasing 805, and a source signal line driver circuit portion 806 are provided. The driver circuit portions 804 to 806 are each connected to an FPC (flexible printed circuit) 807, which is an external input terminal, via a wiring group. Further, the source signal line driver circuit portion 806, the gate signal line driver circuit portion for writing 804, and the gate signal line driver circuit portion for erasing 805 each receive video signals, clock signals, start signals, reset signals, and the like from the FPC 807. Further, a printed wiring board (a PWB) 808 is attached to the FPC 807.

Thin film transistors (TFTs) are used as transistors in the pixel portion 803 and the driver circuit portions 804 to 806. Note that the driver circuit portions 804 to 806 need not necessarily be provided over the same substrate 800 as the pixel portion 803, as described above. For example, they may be provided external to the substrate by employing a TCP (tape carrier package) in which an IC chip is mounted on an FPC having a wiring pattern, or the like. Alternatively, one or more of the driver circuit portions 804 to 806 may be provided over the substrate 800, and the other driver circuit portion or portions may be provided external to the substrate 800.

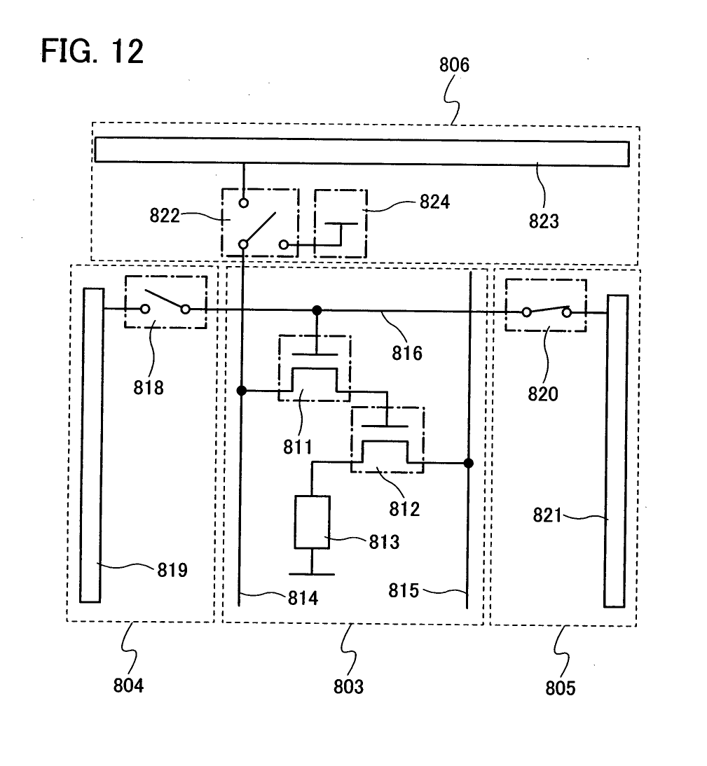

FIG. 12 shows circuits for operating a single pixel. A plurality of pixels are planarly arranged in the pixel portion 803. One pixel includes a first transistor 811, a second transistor 812, and a light-emitting element 813. Further, a source signal line 814 and a current supply line 815 that extend in a column-wise direction and a gate signal line 816 that extends in a row-wise direction are provided. Any of the light-emitting elements described in Embodiment Modes 1 to 10 can be employed as the light-emitting element 813. Here, an example is described in which the light-emitting element with a top emission structure shown in FIG. 1A of Embodiment Mode 1 is employed. That is, an example is described where light is extracted through the substrate 801 side.

The first transistor 811 and the second transistor 812 are each three-terminal elements which include a gate electrode, a drain region, and a source region, and have a channel-forming region between the drain region and the source region. It is difficult to specify which region is the source region or the drain region, because this changes depending on the structure of the transistor, operating conditions, and the like. Therefore, in this specification, the three terminals of the transistor will be differentiated by being referred to as the gate electrode, the first electrode, and the second electrode.

In the gate signal line driver circuit portion for writing 804, the gate signal line 816 is electrically connected to a gate signal line driver circuit for writing 819 via a switch 818. By controlling the switch 818, whether or not the gate signal line 816 is electrically connected to the gate signal line driver circuit for writing 819 is selected.

In the gate signal line driver circuit portion for erasing 805, the gate signal line 816 is electrically connected to a gate signal line driver circuit for erasing 821 via a switch 820. By controlling the switch 820, whether or not the gate signal line 816 is electrically connected to the gate signal line driver circuit for erasing 821 is selected.

In the source signal line driver circuit portion 806, the source signal line 814 is electrically connected to either a source signal line driver circuit 823 or a power source 824 by a switch 822.

In the first transistor 811, a gate electrode is electrically connected to the gate signal line 816, a first electrode is electrically connected to the source signal line 814, and a second electrode is electrically connected to a gate electrode of the second transistor 812.

In the second transistor 812, the gate electrode is electrically connected to the second electrode of the first transistor, as noted above; a first electrode is electrically connected to the current supply line 815, and a second electrode is electrically connected to a first electrode of the light-emitting element 813. A second electrode of the light-emitting element 813 has a fixed potential.

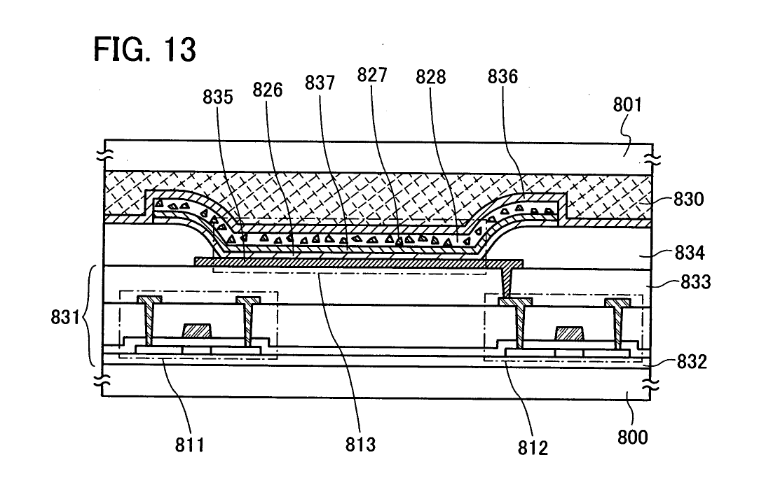

A structure of a pixel of this embodiment mode will be described with reference to FIG. 13. Since this embodiment mode shows a case where the EL panel has a solid-sealed structure, an airtight space between the substrate 800 and the sealing substrate 801 is filled with a filler 830 formed of resin. A structure 831 and the light-emitting element 813 are formed over the substrate 800. As the structure 831, the first transistor 811 and the second transistor 812 which are shown in FIG. 12 are formed over a base layer 832. An interlayer insulating film 833 is formed over the first transistor 811 and the second transistor 812. The light-emitting element 813 and an insulating layer 834 which serves as a partition are formed over the interlayer insulating film 833.

The first transistor 811 and the second transistor 812 are top-gate thin film transistors, and a gate electrode is provided on the side which is opposite to the substrate 800 with respect to the semiconductor layer. There is no particular limitation on the structure of the thin film transistors, the first transistor 811 and the second transistor 812. For example, they may be bottom-gate thin film transistors. Further, in the case of a bottom-gate structure, a TFT in which a protective film is formed over the channel-forming semiconductor layer (a channel protection type TFT) can be used, and also a TFT in which a part of the channel-forming semiconductor layer is concave (a channel etch type TFT) can be used.

Further, the semiconductor layer, in which the channel-forming regions of the first transistor 811 and the second transistor 812 are formed, may be formed of a crystalline semiconductor or an amorphous semiconductor.

Specific examples of a crystalline semiconductor layer are semiconductor layers including single crystal silicon, polycrystalline silicon, silicon germanium or the like. Such semiconductor layers may be formed using laser crystallization, or using crystallization by solid phase epitaxy growth employing nickel or the like.

In a case where the semiconductor layer is formed of an amorphous semiconductor such as an amorphous silicon, it is preferable that all the transistors included in the pixel portion 803 are n-channel thin film transistors. In other cases, the transistors included in the pixel portion 803 may be either n-channel transistors or p-channel transistors, or both.

Further, transistors used in the driver circuit portions 804 to 806 may have similar structural diversity to the first transistor 811 and the second transistor 812 in the pixel portion 803. For the driver circuit portions 804 to 806, depending on a property of the transistors, all the driver circuit portions may be formed using thin film transistors. Alternatively, one or more of the driver circuit portions may be formed using thin film transistors, and the other driver circuit portion or portions may be formed using an IC chip. Further, transistors in the driver circuit portions 804 to 806 may be constructed by using either n-channel transistors or p-channel transistors, or alternatively, both n-channel transistors and p-channel transistors can be used to fabricate transistors in the driver circuit portions 804 to 806.

FIG. 13 shows an example where the light-emitting element 120 shown in FIG. 1A of Embodiment Mode 1 is employed as the light-emitting element 813. The light-emitting element 813 includes a light-emitting layer 837 between a first electrode 835 and a second electrode 836. Also included are a first dielectric layer 826 that is located between the first electrode 835 and the light-emitting layer 837, and a second dielectric layer 828, in which light-scattering fine particles 827 are dispersed, that is interposed between the light-emitting layer 837 and the second electrode 836. The first electrode 835 has a reflective property, and serves as a cathode. The second electrode 836 has a light-transmitting property, and serves as an anode. Light generated in the light-emitting layer 837 is extracted through the second electrode 836. In this example, a structure is employed in which the first electrode 835, the first dielectric layer 826, the light-emitting layer 837, the second dielectric layer 828 in which light-scattering fine particles 827 are dispersed, and the second electrode 836 are stacked in that order over the interlayer insulating film 833. In this embodiment mode, the amount of light which is incident on the interface between the second dielectric layer 828 and the second electrode 836 that is totally reflected is decreased by the light-scattering fine particles 827 dispersed in the second dielectric layer 828, which results in improvement of the light extraction efficiency of the light-emitting element 813.

Note that the first electrode 835 corresponds to the reflective electrode 103, the first dielectric layer 826 corresponds to the first dielectric layer 107, the light-emitting layer 837 corresponds to the light-emitting layer 104, the second dielectric layer 828 in which light-scattering fine particles 827 are dispersed corresponds to the second dielectric layer 108 in which light-scattering fine particles 106 are dispersed, and the second electrode 836 corresponds to the transmissive electrode 105. It should be noted that there is no particular limitation on the structure of the light-emitting element described in this embodiment mode, and a light-emitting element described in another embodiment mode can be employed. As long as a light-emitting element has a structure that includes at least a dielectric layer in which light-scattering fine particles are dispersed and a light-emitting layer interposed between a pair of electrodes, or as long as light-scattering fine particles and particles of light-emitting material are dispersed in a light-emitting layer which is interposed between a pair of electrodes, any structure can be used for the light-emitting element 813.

The first electrode 835 is connected to the second electrode of the second transistor 812 through a contact hole provided in the interlayer insulating film 833.

Further, in this embodiment mode, the solid sealed structure described in Embodiment Mode 3 is employed as the sealing structure of the EL panel. However, it should be emphasized that a sealing structure of another embodiment mode can also be employed. Further, a top emission structure has been employed for the light-emitting element 813; however, a light-emitting element with a bottom emission structure can also be employed, in which the positions of the first electrode 835 having a reflective property and the second electrode 836 having a light-transmitting property, and the positions of the first dielectric layer 826 and the second dielectric layer 828 having the dispersed light-scattering fine particles 827 are reversed.

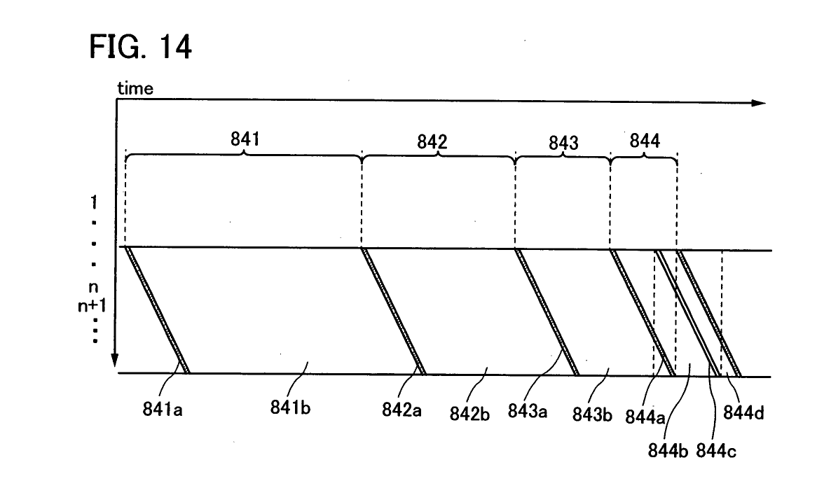

A driving method of the EL panel of this embodiment mode will be described with reference to FIG. 14. FIG. 14 shows an operation method of a frame over time. In FIG. 14, the horizontal axis represents the processing time and the vertical axis shows the numbers of scanning stages of a gate signal line.

When images are displayed using the EL panel of this embodiment mode, rewrite operations and display operations of images are conducted repeatedly during the display period. There is no particular limitation on the number of rewrite operations. However, the rewrite operation is preferably conducted about sixty times or more per second so that a flicker in the images is not conspicuous. Here, a period in which the rewrite operations and display operations for one image (one frame) are conducted is referred to as one frame period.

As shown in FIG. 14, one frame is temporally divided into four subframes: subframe 841, subframe 842, subframe 843, and subframe 844, which collectively include a writing period 841a, a writing period 842a, a writing period 843a, a writing period 844a, and a retention period 841b, a retention period 842b, a retention period 843b, and a retention period 844b. A light-emitting element to which a signal for emitting light has been applied is in a light-emitting state during the retention periods. The ratio of the lengths of the retention periods of the subframes is: first subframe 841 second subframe 842: third subframe 843: fourth subframe 844=2³:2²:2¹:2⁰=8:4:2:1. This allows a 4-bit gray scale to be displayed. Note that the number of bits and the number of gray scales are not limited to the numbers described here. For example, one frame may include eight subframes, enabling an 8-bit gray scale to be displayed.

Operation for one frame will be described. First, in the subframe 841, writing operations are performed in sequence from the first row to the last row. Therefore, the starting time of the writing period differs for each row. The retention period 841b starts in sequence in the rows in which the writing period 841a has finished. During the retention period, the light-emitting element applied with a signal for light emitting is in a light-emitting state. Further, operation proceeds to the next subframe 842 in sequence in the rows in which the retention period 841b has finished, and similarly to the case of the subframe 841, writing operations are performed in sequence from the first row to the last row.

Operations described above are repeated until the retention period 844b of the subframe 844 has finished. When operation in the subframe 844 has finished, an operation in the next frame is started. Thus, the accumulation of the light-emitting time in each subframe corresponds to the light-emitting time of each light-emitting element in one frame period. By combining pixels which have different light-emitting times, various display colors of differing luminance and chromaticity can be constructed.

When it is desired, as shown in subframe 844, to forcibly terminate a retention period in a row in which writing has finished and the retention period has started prior to completion of the writing operation of the last row, preferably an erasing period 844c is provided after the retention period 844b to forcibly stop light emission. The row in which light emission is forcibly stopped does not emit light for a certain period of time (this period of time is referred to as a non-light emitting period 844d). As soon as the writing period of the last row has finished, a writing period of a next sub-frame (or a next frame) starts in sequence from the first row. This operation prevents the writing period in the subframe 844 from overlapping with the writing period in the next subframe.

In this embodiment mode, the subframes 841 to 844 are arranged in order from the subframe with the longest retention period to the subframe with the shortest retention period. However, the subframe 841 to 844 are not necessarily arranged in this order. For example, the subframes 841 to 844 may be arranged in order from the subframe with the shortest retention period to the subframe with the longest one. Alternatively, the sub-frames may be arranged in random order, regardless of the length of the retention period. Furthermore, a subframe may be further divided into a plurality of frames. That is, in a period where the same picture signal is being applied, scanning of gate signal lines may be performed a plurality of times.

Operations of the circuit shown in FIG. 12 in the writing period and the erasing period will now be described. First, an operation in the writing period will be described. In the writing period, the gate signal line 816 of an nth row (where n is a natural number) is electrically connected to the gate signal line driver circuit for writing 819 by the switch 818. Meanwhile, the gate signal line 816 of an nth row is disconnected from the gate signal line driver circuit for erasing 821 by the switch 820.

The source signal line 814 is electrically connected to the source signal line driver circuit 823 by the switch 822. A signal is input to a gate of the first transistor 811, which is connected to the gate signal line 816 of the nth row (where n is a natural number), thereby turning on the first transistor 811. At this time, picture signals are input to the source signal lines 814 of the first column through to the last column simultaneously. Note that the picture signals input to the source signal lines 814 of the columns are independent of each other.

The picture signal input to the source signal line 814 is then input to the gate electrode of the second transistor 812 via the first transistor 811 which is connected to the source signal line 814. Then, depending on the current value of the signal, the light-emitting element 813 either emits light or does not emit light. For example, in a case where the second transistor 812 is a p-channel transistor, the light-emitting element 813 emits light when a low level signal in input to the gate electrode of the second transistor 812. On the other hand, in a case where the second transistor 812 is an n-channel transistor, current flows to the light-emitting element 813 when a high level signal is input to the gate electrode of the second transistor 812, which allows the light-emitting element 813 to emit light.

Next, an operation in the erasing period will be described. In the erasing period, the gate signal line 816 of the nth row (where n is a natural number) is electrically connected to the gate signal line driver circuit for erasing 821 via the switch 820. Meanwhile, the gate signal line 816 of the nth row is disconnected from the gate signal line driver circuit for writing 819 by the switch 818. The source signal line 814 is electrically connected to the power source 824 by the switch 822. A signal is input to the gate of the first transistor 811 which is connected to the gate signal line 816 of the nth row, and the first transistor 811 is thereby turned on. At this time, erase signals are simultaneously input to the source signal lines 814 of the first column through to the last column.

The erase signal input to the source signal line 814 is then input to the gate electrode of the second transistor 812 via the first transistor 811 which is connected to the source signal line 814. Supply of current from the current supply line 815 to the light-emitting element 813 is blocked by the signal input to the second transistor 812, so that the light-emitting element 813 stops emitting light. For example, in a case where the second transistor 812 is a p-channel transistor, the light-emitting element 813 stops emitting light when a high level signal is input to the gate electrode of the second transistor 812. On the other hand, in a case where the second transistor 812 is an n-channel transistor, the light-emitting element 813 stops emitting light when a low level signal is input to the gate electrode of the second transistor 812.

In the erasing period, a signal for erasing is input to the nth row (where n is a natural number) by an operation such as that described above. However, as mentioned above, there are cases where another row (the mth row, where m is a natural number) starts a writing period when the nth row is in an erasing period. In such a case, since it is necessary to use the source signal line 814 of the same column to input a signal for erasing to the nth row and a signal for writing to the mth row, an operation described below is preferably carried out.

Immediately after the light-emitting element 813 in the nth row is made to stop emitting light by the above-described operation in the erasing period, the gate signal line 816 and the gate signal line driver circuit for erasing 821 are disconnected from each other, while the switch 822 is switched to connect the source signal line 814 to the source signal line driver circuit 823. Then, the gate signal line 816 and the gate signal line driver circuit for writing 819 are connected to each other by the switch 818. Then, a signal is selectively input from the gate signal line driver circuit for writing 819 to the gate signal line 816 of the mth row, and the first transistor 811 is turned on. Meanwhile, signals for writing are input to the source signal lines 814 of columns from the first to the last column, from the source signal line driver circuit 823. According to this signal, a light-emitting element in the mth row either emits light or does not emit light.

Immediately after the writing period for the mth row has terminated as mentioned above, the erasing period starts in the (n+1)th row. Therefore, the gate signal line 816 and the gate signal line driver circuit for writing 819 are disconnected from each other by the switch 818, and meanwhile the gate signal line 816 is connected to the gate signal line driver circuit for erasing 821 by the switch 820. Further, the switch 822 switches and connects the source signal line 814 to the power source 824. A signal is input to the gate signal line 816 of the (n+1)th row from the gate signal line driver circuit for erasing 821 to turn on the first transistor 811, and meanwhile an erase signal is input from the power source 824. In this manner, immediately after the erasing period of the (n+1)th row has finished, the writing period of the mth row starts. Subsequently, erasing periods and writing periods are repeated alternately in a similar manner through to the erasing period of the last row.

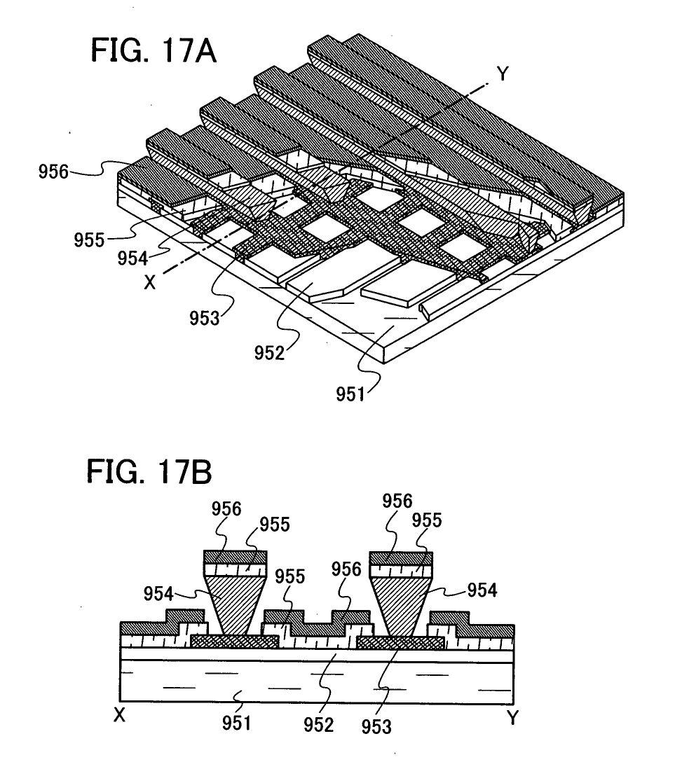

Note that, in this embodiment mode, description was made with reference to an active matrix EL panel; however, display devices from Embodiment Modes 1 to 10 can be applied to passive matrix EL panels. For example, FIG. 17A shows a perspective diagram of an example of a passive matrix EL panel which is manufactured applying the invention. Further, FIG. 17B shows an example of a cross section taken along the broken line X-Y in FIG. 17A.

In FIGS. 17A and 17B, an electrode 952, a layer 955, and an electrode 956 are stacked in that order over a substrate 951. One of the electrode 952 and the electrode 956 has a reflective property, and the other has a light transmitting property. The layer 955 includes at least a light-emitting layer and a dielectric layer in which light-scattering fine particles are dispersed as shown in Embodiment Modes 1, 3, 5, 7, and 9. Alternatively, the layer 955 includes at least a light-emitting layer in which particles of light-emitting material and light-scattering fine particles are dispersed as shown in Embodiment Modes 2, 4, 6, 8, and 10. Note that the dielectric layer in which light-scattering fine particles are dispersed or the light-emitting layer in which light-scattering fine particles are dispersed is provided so as to be in contact with the electrode having a light transmitting property. By employing such a structure, the amount of light which is incident on the interface between the electrode having a light transmitting property and the dielectric layer or the light-emitting layer that is totally reflected is decreased by the light-scattering fine particles dispersed in the dielectric layer or the light-emitting layer. Therefore, the light extraction efficiency of a light-emitting element can be improved.

Further, an end portion of the electrode 952 and another part of the electrode 952 are covered by an insulating layer 953. The insulating layer 953 has a plurality of openings, and in the openings, the electrode 952, the layer 955, and the electrode 956 are stacked in that order. Further, over a region where the opening in the insulating layer 953 is not formed, a partition layer 954 is provided. A sidewall of the partition layer 954 has an inclination such that the closer the distance to a surface of the substrate, the shorter the distance between the sidewall and another sidewall of the partition layer 954. That is, a cross section taken along a short side of the partition layer 954 has a trapezoidal shape, and the base of the trapezoid (a side of the trapezoid that is parallel to a surface of the insulating layer 953 and is in contact with the insulating layer 953) is shorter than the upper side of the trapezoid (a side of the trapezoid that is parallel to the surface of the insulating layer 953 and is not in contact with the insulating layer 953). By providing the partition layer 954 in this manner, it is possible to electrically separate the electrode 956 from the adjacent electrode.

### Embodiment Mode 12

Since the light extraction efficiency of the light emitting element in the display devices described in Embodiment Modes 1 to 10 is improved, the display devices can realize high luminance and low power consumption. Therefore, by applying these display devices to display portions, a clear, bright display with low power consumption can be obtained.

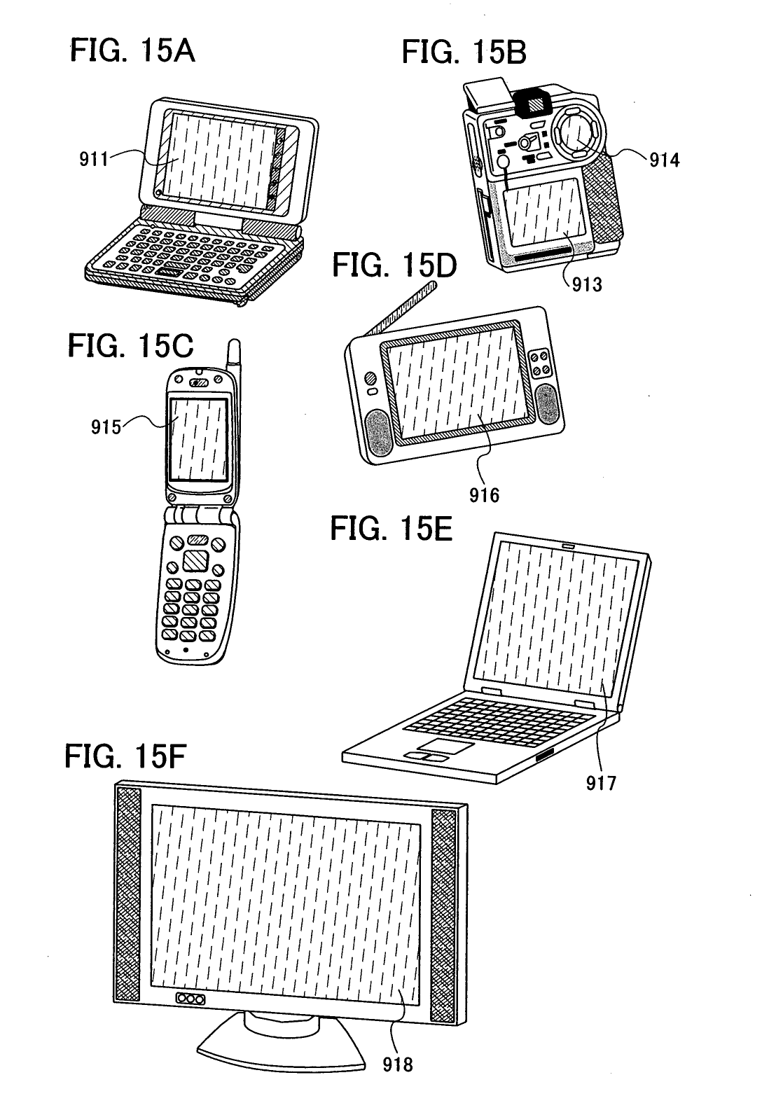

The display devices in Embodiment Modes 1 to 10 can be suitably applied to a display portion for a battery-powered electronic device or a display portion of a large screen display device or an electronic device. For example, they can be applied to television devices (e.g. a television, a television receiver), digital cameras, digital video cameras, portable telephone devices (e.g. portable telephones), portable information terminals such as PDAs, portable game machines, monitors, computers, sound reproduction devices such as car audio devices, image reproducing devices equipped with a recording medium such as home game machines, and the like. Specific examples of these devices will be described with reference to FIGS. 15A to 15F. A display device which is applied to the display portion may have an active matrix structure or a passive matrix structure.

A display device of the invention can be applied to a display portion 911 of a portable information terminal device shown in FIG. 15A.

A display device of the invention can be applied to a viewfinder 914 and a display portion 913 for displaying photographed images in a digital video camera shown in FIG. 15B.

A display device of the invention can be applied to a display portion 915 of a portable telephone shown in FIG. 15C.

A display device from any of the preceding embodiment modes can be applied to a display portion 916 of a portable television device shown in FIG. 15D. Further, the display device can be applied to a display portion of a wide range of types of television devices, including small-sized television devices in a portable terminal such as a portable telephone, medium-sized ones which can be carried, and large-sized ones (e.g., 40 inches or more).

A display device of the invention can be applied to a display portion 917 of a notebook computer or laptop computer shown in FIG. 15E.

A display device of the invention can be applied to a display portion 918 of a television device shown in FIG. 15F. Further, display devices of the preceding embodiment modes can be applied to display portions in a wide range of types of television devices including small-sized television devices in a portable terminal such as the portable telephone shown in FIG. 15C, medium-sized television devices which can be carried, and large-sized television devices (e.g., 40 inches or more).

Electronic devices relating to this embodiment mode can exhibit high luminance and low power consumption by employing a light-emitting element of the invention or by using a display device including a light-emitting element of the invention in a display portion.

### Embodiment Mode 13

In this embodiment mode, a mode in which a display device is applied to a planar lighting device will be described. Besides being employed in display portions, the display devices in Embodiment Modes 1 to 10 can also be employed in planar lighting devices. For example, in a case where a liquid crystal panel is employed in a display portion of an electronic device given as an example in this embodiment mode, a display device from any of the preceding embodiment modes can be employed as a backlight of the liquid crystal panel. When employing the display device as a lighting device, it is preferable to use a passive matrix display device, such as that shown in FIGS. 17A and 17B.

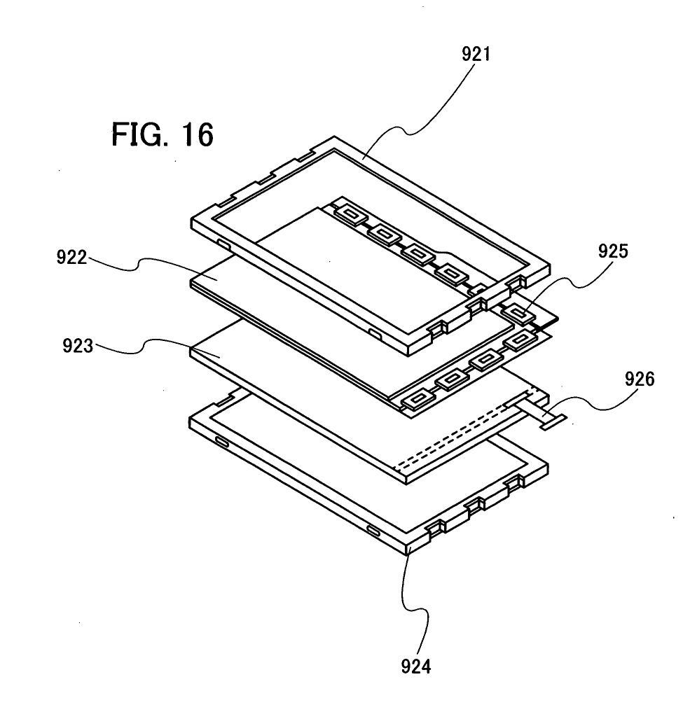

FIG. 16 is an example of a liquid crystal display device employing a display device as a backlight. The liquid crystal display device shown in FIG. 16 includes a housing 921, a liquid crystal layer 922, a backlight 923, and a housing 924. The liquid crystal layer 922 is connected to a driver IC 925. A display device of the invention is employed as the backlight 923, and is supplied with current by a terminal 926.

Further, the liquid crystal display device including the backlight of this embodiment mode can be employed as a display portion in all kinds of electronic devices, such as those shown in Embodiment Mode 12.

A backlight that is bright and has low power consumption can be obtained by employing a display device to which the invention is applied. Further, the display device to which the invention is applied is a surface emission lighting device, and it is possible to increase the area of the emitting surface. Therefore, the area of the backlight can be increased so that the area of the liquid crystal display device can also be increased. Additionally, since the display device is thin and has low power consumption, a thinner display device with lower power consumption can be obtained.

The present application is based on Japanese priority application No. 2006-154154 filed on Jun. 2, 2006 with the Japanese Patent Office, the entire contents of which are hereby incorporated by reference.

What is claimed is:

1. A light-emitting element comprising:
a light-emitting layer interposed between a first electrode and a second electrode, wherein light emitted from the light-emitting layer is extracted through the second electrode; and
a dielectric layer interposed between the second electrode and the light-emitting layer,
wherein a plurality of light-scattering fine particles are dispersed in the dielectric layer.

2. A light-emitting element according to claim 1,
wherein at least one of the light-scattering fine particles has a diameter in the range from 2 to 800 nm, inclusive.

3. A light-emitting element according to claim 1,
wherein the light-scattering fine particles have a refractive index which is equal to or higher than that of the first electrode.

4. A light-emitting element comprising:
a light-emitting layer interposed between a first electrode and a second electrode, the light-emitting layer comprising a binder, a plurality of particles of light-emitting material and a plurality of light-scattering fine particles,
wherein the plurality of particles of light-emitting material and the plurality of light-scattering fine particles are dispersed in the binder.

5. A light-emitting element according to claim 4,
wherein at least one of the light-scattering fine particles has a diameter in the range from 2 to 800 nm, inclusive.

6. A light-emitting element according to claim 4,
wherein the light-scattering fine particles have a refractive index which is equal to or higher than that of the first electrode.

7. A light-emitting element comprising:
a first electrode;
a light-emitting layer over the first electrode;
a first dielectric layer over the light-emitting layer;
a second dielectric layer over the first dielectric layer; and
a second electrode over the second dielectric layer,
wherein light emitted from the light-emitting layer is extracted through the second electrode,
wherein a plurality of first light-scattering fine particles are dispersed in the first dielectric layer, and
wherein a plurality of second light-scattering fine particles are dispersed in the second dielectric layer.

8. A light-emitting element according to claim 7,
wherein at least one of the light-scattering fine particles has a diameter in the range from 2 to 800 nm, inclusive.

9. A light-emitting element according to claim 7,
wherein at least one of the light-scattering fine particles has a diameter in the range from 2 to 800 nm, inclusive.

10. A light-emitting element according to claim 7,
wherein the first light-scattering fine particles have a refractive index which is equal to or higher than that of the first electrode.

11. A light-emitting element according to claim 7,
wherein the second light-scattering fine particles have a refractive index which is equal to or higher than that of the first electrode.

12. A light-emitting device comprising:
a light-emitting element interposed between a pair of substrates, the light-emitting element comprising a light-emitting layer interposed between a first electrode and a second electrode,
wherein light emitted from the light-emitting layer is extracted through the second electrode,
wherein the light-emitting element further comprises a dielectric layer between the second electrode and the light-emitting layer, and
wherein a plurality of light-scattering fine particles are dispersed in the dielectric layer.

13. A light-emitting device according to claim 12,
wherein at least one of the light-scattering fine particles has a diameter in the range from 2 to 800 nm, inclusive.

14. A light-emitting device according to claim 12,
wherein the light-scattering fine particles have a refractive index which is equal to or higher than that of the first electrode.

15. A light-emitting device according to claim 12, further comprising a solid filler between the light-emitting element and one of the pair of substrates.

16. A light-emitting device comprising:
a light-emitting element interposed between a pair of substrates, the light-emitting element comprising a light-emitting layer interposed between a first electrode and a second electrode,
wherein the light-emitting layer comprises a binder, a plurality of particles of light-emitting material, and a plurality of light-scattering fine particles, and
wherein the plurality of particles of light-emitting material and the plurality of light-scattering fine particles are dispersed in the binder.

17. A light-emitting device according to claim 16,
wherein at least one of the light-scattering fine particles has a diameter in the range from 2 to 800 nm, inclusive.

18. A light-emitting device according to claim 16,
wherein the light-scattering fine particles have a refractive index which is equal to or higher than that of the first electrode.

19. A light-emitting device according to claim 16, further comprising a solid filler between the light-emitting element and one of the pair of substrates.

20. A light-emitting device comprising:
a light-emitting element interposed between a pair of substrates, the light-emitting element comprising:
a first electrode;
a light-emitting layer over the first electrode;
a first dielectric layer over the light-emitting layer;
a second dielectric layer over the first dielectric layer; and
a second electrode over the second dielectric layer,
wherein light emitted from the light-emitting layer is extracted through the second electrode,
wherein a plurality of first light-scattering fine particles are dispersed in the first dielectric layer, and
wherein a plurality of second light-scattering fine particles are dispersed in the second dielectric layer.

21. A light-emitting device according to claim 20,
wherein at least one of the light-scattering fine particles has a diameter in the range from 2 to 800 nm, inclusive.

22. A light-emitting device according to claim 20,
wherein at least one of the light-scattering fine particles has a diameter in the range from 2 to 800 nm, inclusive.

23. A light-emitting device according to claim 20,
wherein the first light-scattering fine particles have a refractive index which is equal to or higher than that of the first electrode.

24. A light-emitting device according to claim 20,
wherein the second light-scattering fine particles have a refractive index which is equal to or higher than that of the first electrode.

25. A light-emitting device according to claim 20, further comprising a solid filler between the light-emitting element and one of the pair of substrates.

26. An electronic device comprising a display portion which comprises a light-emitting element according to claim 1.

27. An electronic device comprising a display portion which comprises a light-emitting element according to claim 4.

28. An electronic device comprising a display portion which comprises a light-emitting element according to claim 7.

29. An electronic device comprising a display portion which comprises a light-emitting device according to claim 12.

30. An electronic device comprising a display portion which comprises a light-emitting device according to claim 16.

31. An electronic device comprising a display portion which comprises a light-emitting device according to claim 20.
